(19) United States
(12) Patent Application Publication
(10) Pub. No.: US 2024/0357921 A1
(43) Pub. Date: Oct. 24, 2024

(54) LUMINESCENT MATERIAL MADE OF PLATINUM COMPLEX HAVING NNCN TETRADENTATE LIGAND, AND APPLICATION THEREOF

(71) Applicant: GUANGDONG AGLAIA OPTOELECTRONIC MATERIALS CO., LTD, Foshan (CN)

(72) Inventors: Xinwei Wu, Foshan (CN); Lei Dai, Foshan (CN); Lifei Cai, Foshan (CN)

(21) Appl. No.: 18/671,269

(22) Filed: May 22, 2024

Related U.S. Application Data
(63) Continuation of application No. PCT/CN2022/123701, filed on Oct. 4, 2022.

(30) Foreign Application Priority Data
Nov. 29, 2021 (CN) 202111430026.6

(51) Int. Cl. H10K 85/30; C07F 15/00; C09K 11/06; H10K 50/11; H10K 50/16

(52) U.S. Cl. CPC H10K 85/346; C07F 15/0086; C09K 11/06; C09K 2211/1074; C09K 2211/185; H10K 50/11; H10K 50/16

(57) ABSTRACT

A luminescent material made of platinum complex having NNCN tetradentate ligand, and applications thereof in light emitting diode are provided. The platinum complex is a compound has a structure as shown in Formula (I). When applied to an organic light emitting diode, and has the potential to be applied to the field of organic electroluminescent devices. An organic electroluminescent device is further provided, which includes a cathode, an anode and an organic layer. The organic layer is selected from the group consisting of an electron hole injection layer, an electron hole transport layer, a luminescent layer, an electron hole blocking layer, an electron transport layer, an electron injection layer, and any combination thereof. At least one of the organic layers contains a compound represented by structural formula (I).

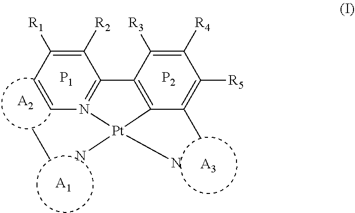

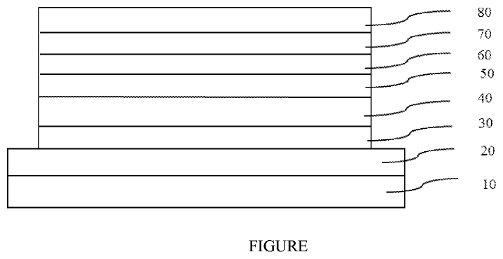

### CROSS-REFERENCE TO RELATED APPLICATIONS

This application is a continuation of PCT international patent application No. PCT/CN2022/123701, filed on Oct. 4, 2022, which claims priority to Chinese patent application No. 202111430026.6, filed on Nov. 29, 2021. The contents of the above-identified applications are hereby incorporated herein in their entireties by reference.

### TECHNICAL FIELD

The present disclosure relates to the field of luminescent material, in particular, to a luminescent material made of platinum complex having NNCN tetradentate ligand, and applications thereof in light emitting diode.

### BACKGROUND

Organometallic complex luminescent material is a new cross research field developed after inorganic luminescent materials. Compared with inorganic luminescent materials, organometallic complex luminescent materials have the advantages of high luminescence efficiency, great brightness, wide viewing angle and fast response speed, and the like. The organometallic complex luminescent materials have heavy metal complexes, such as iridium (Ir) complex and platinum (Pt) complex, with d6 and d8 electronic structures. Due to the strong spin-orbit coupling of the electronic structure of d6 and d8, the probability of intersystem cross from the singlet state to triplet state is increased, the phosphorescence efficiency is greatly improved, the phosphorescence lifetime is shortened, the phosphorescence quenching is reduced, and the phosphorescence phenomenon at room temperature is realized. The light emitting color of OLEDs can be controlled by the structural design of the luminescent materials. The OLEDs can include one luminescent layer or multiple luminescent layers to achieve the desired spectrum. Currently, green phosphorescent materials are the most developed class of phosphorescent materials. However, the development of deep red phosphorescent materials and blue phosphorescent materials lags far behind that of green phosphorescent materials due to the limitation of small energy gaps and the mismatch of the main materials, etc., respectively.

Research on red phosphorescent materials has become a bottleneck in the development of high-quality information display. The main reasons for this situation are shown herein: (1) the energy level difference of compounds emitting red light is small, which poses challenges in designing of ligands for red phosphorescent materials; (2) the presence of strong π-π bond interactions or strong charge transfer properties in the red phosphorescent material system may exacerbate the aggregation of molecules and easily lead to quenching phenomena; (3) red phosphorescent material exhibit low stability, therefore, suitable red phosphorescent materials undergo a red-shift by lowering the energy gap (Eg) and reducing the energy required for the energy level transition.

At the same time, in order to adapt to requirements of industrialization, for the red phosphorescent materials devices, in terms of the performance, such as luminescence efficiency, service life should be further improved.

### SUMMARY

In view of the problems above, the present disclosure provides a class of luminescent materials made of platinum complex having NNCN tetradentate ligand. The class of luminescent materials has good luminescence efficiency when they are applied in organic light emitting diodes.

The present disclosure provides an organic light emitting diodes having the platinum complex.

A platinum complex having NNCN tetradentate ligand as shown in formula (I),

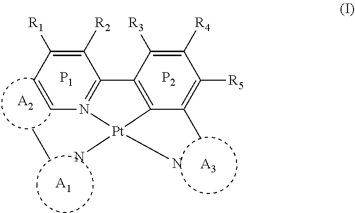

wherein A₁ and A₃ are each independently selected from R₀ substituted or unsubstituted N-containing C₄-C₆₀ heteroaryl groups,
A₂ is selected from R₀ substituted or unsubstituted C₆-C₆₀ aryl groups, or substituted or unsubstituted C₄-C₆₀ heteroaryl groups;
a ring formed by coordination bonds of A₁, A₂, P₁ and Pt is a six-membered ring;
a ring formed by coordination bonds of P₁, P₂ and Pt is a five-membered ring;
a ring formed by coordination bonds of P₂, A₃ and Pt is a five-membered ring;
R₀-R₅ are each independently selected from hydrogen atom, deuterium atom, halogen, amino group, carbonyl group, carboxyl group, alkythio, cyano group, sulfonyl group, phosphino group, substituted or unsubstituted C₁-C₂₀ alkyl groups, substituted or unsubstituted C₃-C₂₀ cycloalkyl groups, substituted or unsubstituted C₂-C₂₀ alkenyl groups, substituted or unsubstituted C₁-C₂₀ alkoxyl groups, substituted or unsubstituted C₆-C₃₀ aryl groups, or substituted or unsubstituted C₃-C₃₀ heteroaryl groups, or adjacent R₀-R₅ groups are capable of forming rings;
wherein substituted groups are selected from halogen, amino group, cyano group or C₁-C₄ alkyl groups; and
heteroatoms in the heteroaryl group is selected from the group consisting of N, S, O, and any combination thereof.

In some embodiments, R₀-R₅ are each independently selected from hydrogen atom, deuterium atom, halogen, amino group, alkythio, cyano group, substituted or unsubstituted C₁-C₆ alkyl groups, substituted or unsubstituted C₃-C₆ cycloalkyl groups, substituted or unsubstituted C₂-C₆ alkenyl groups, substituted or unsubstituted C₁-C₆ alkoxyl groups, substituted or unsubstituted C₆-C₁₂ aryl groups, or substituted or unsubstituted C₃-C₆ heteroaryl groups.

In some embodiments, R₀-R₅ are each independently selected from hydrogen atom, deuterium atom, halogen, C₁-C₄ alkyl groups, cyano group, substituted or unsubstituted C₃-C₆ cycloalkyl groups, substituted or unsubstituted C₆-C₁₂ aryl groups, or substituted or unsubstituted C₃-C₆ heteroaryl groups.

In some embodiments, R₀-R₅ are each independently selected from hydrogen atom, deuterium atom, methyl group, iso-propyl group, iso-butyl group, tert-butyl group, cyano group, substituted or unsubstituted cyclopentyl group, substituted or unsubstituted cyclohexyl group, substituted or unsubstituted phenyl group, substituted or unsubstituted pyridyl group, substituted or unsubstituted pyrazinyl group, or substituted or unsubstituted pyrimidyl group.

In some embodiments, R₀-R₅ are each independently selected from hydrogen atom, deuterium atom, methyl group, tert-butyl group, substituted or unsubstituted cyclopentyl group, substituted or unsubstituted cyclohexyl group, substituted or unsubstituted phenyl group, or substituted or unsubstituted pyridyl group.

A₁ is selected from R₀ substituted or unsubstituted C₄-C₂₀ heteroaryl groups, which includes at least one N atom; and a ring formed by coordination bonds of A₁, A₂ and Pt is a five-membered N substituted heterocyclic ring or a six-membered N substituted heterocyclic ring. A₃ is selected from R₀ substituted or unsubstituted C₄-C₂₀ heteroaryl groups, which includes one N atom or two N atoms; and a ring formed by coordination bonds of A₃ and Pt is a five-membered N substituted heterocyclic ring or a six-membered N substituted heterocyclic ring.

A₂ is selected from R₀ substituted or unsubstituted C₆-C₂₀ aryl groups, or substituted or unsubstituted C₄-C₂₀ heteroaryl groups.

A₂ is selected from R₀ substituted or unsubstituted C₄-C₁₂ heteroaryl groups, which includes at least one N atom; and a ring formed by coordination bonds of A₂ and A₁ is a five-membered N substituted heterocyclic ring or a six-membered N substituted heterocyclic ring, and a position of A₂ is bonded to A₁ is the N atom.

In some embodiments, A₁ is selected from following groups, and dotted lines represent a bond between A and A₂ (not limited to the structures listed in the table herein),

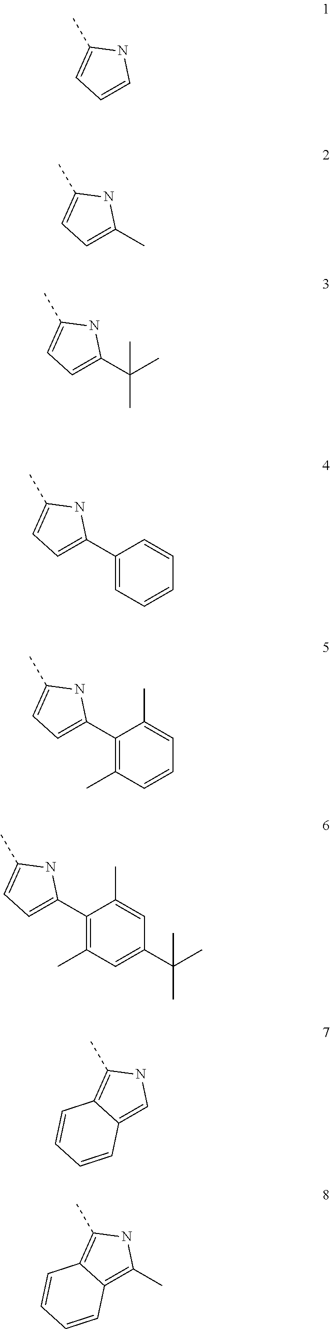

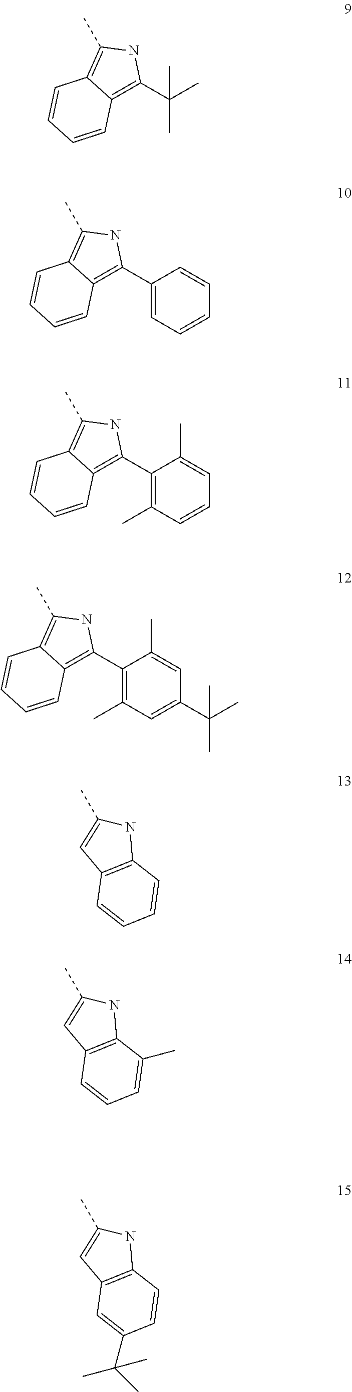

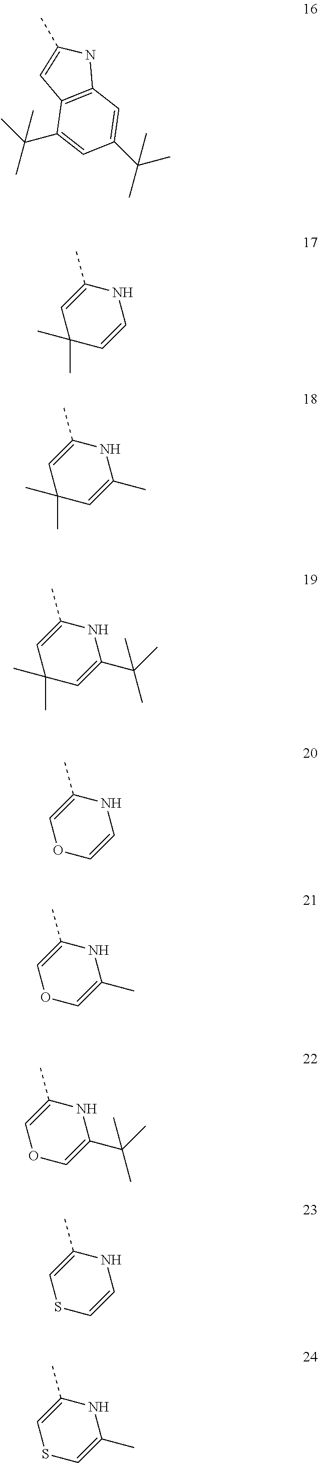

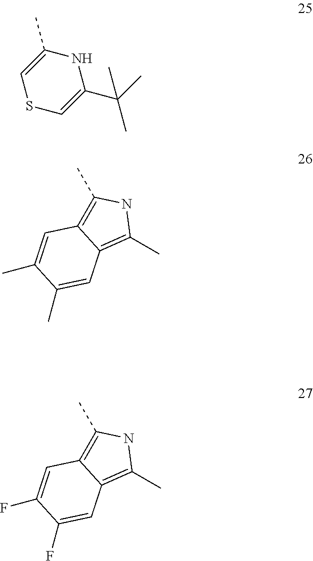

A₂ is selected from following groups, and dotted lines represent a bond between A₁ and A₂ (not limited to the structures listed in the table herein),

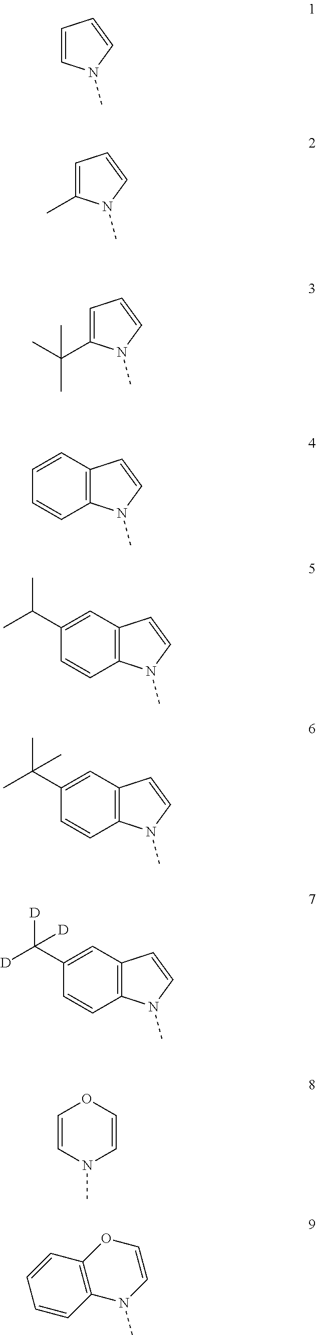

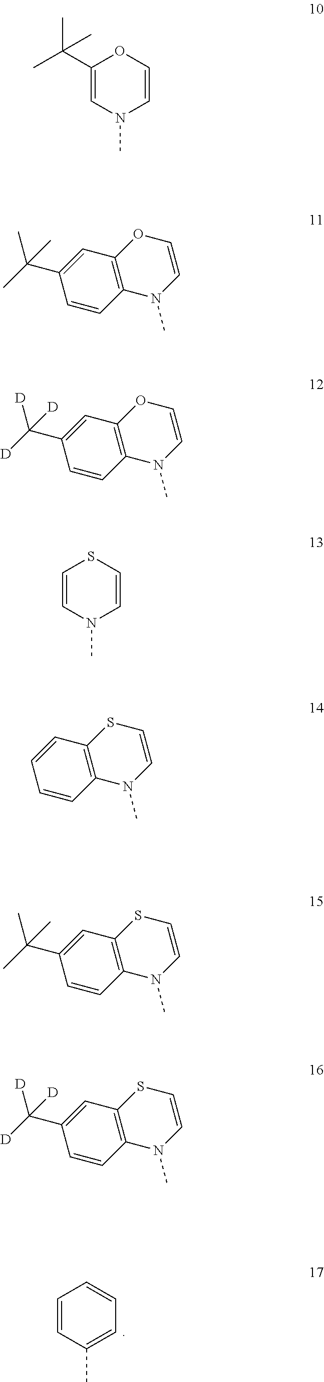

A₃ is selected from following groups, and dotted lines represent a bond between A₃ and P₂ (not limited to the structures listed in the table herein),

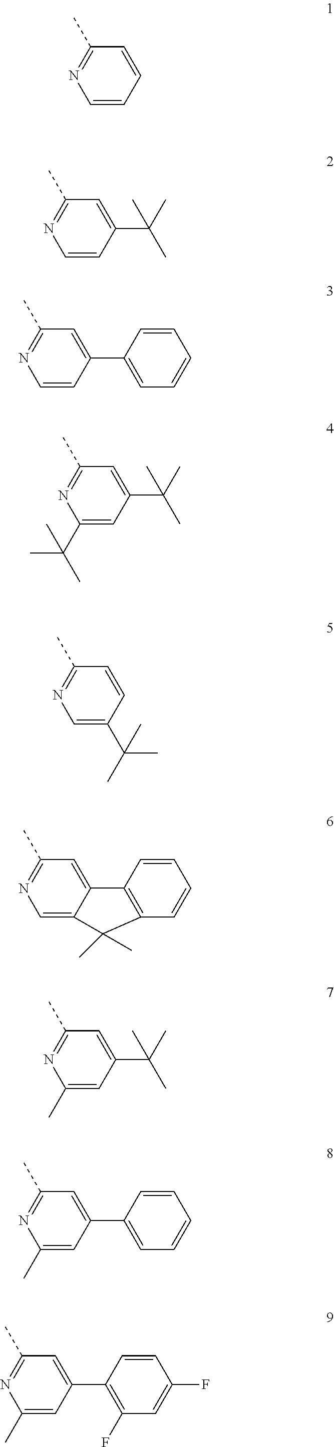

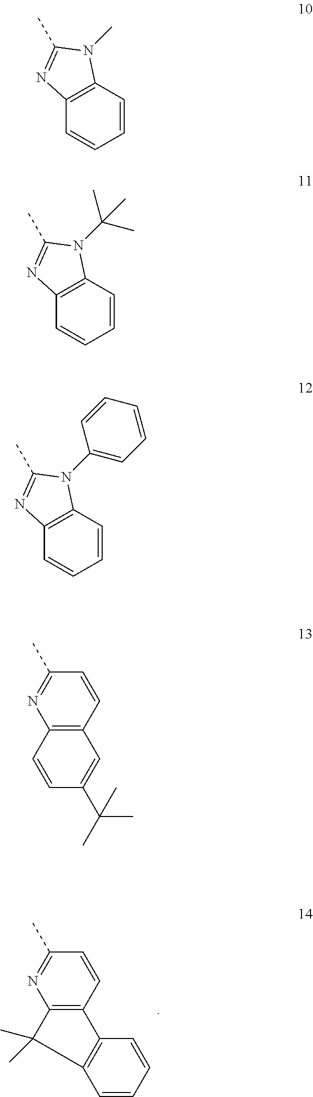

In some embodiments, the formula (I) is selected from one of following structures (not limited to the structures listed in the table herein).

Examples of platinum complexes in accordance with the present disclosure are listed below, and the platinum complexes are not limited to the structures listed herein.

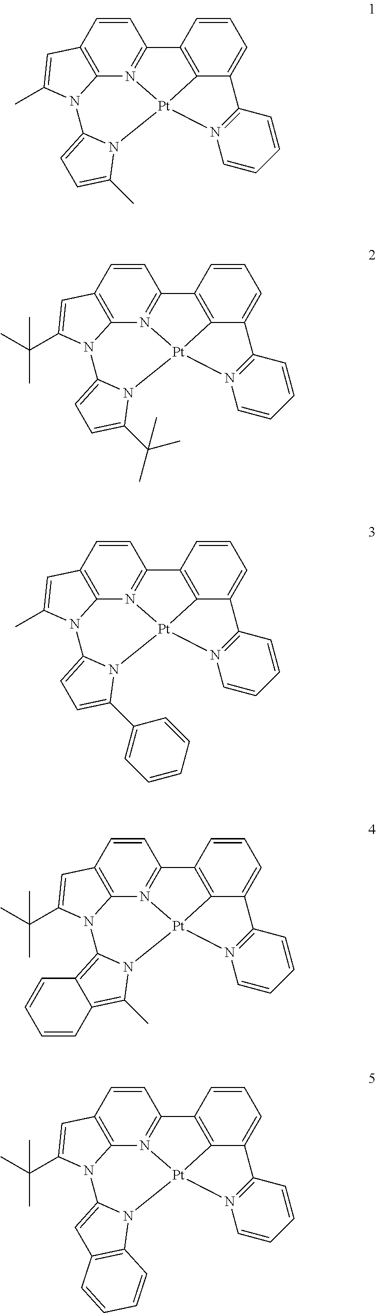

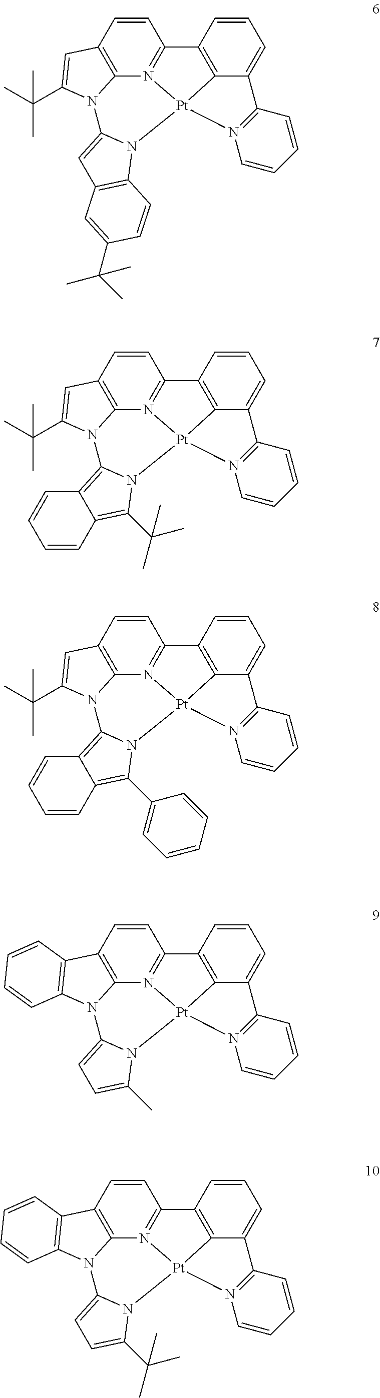

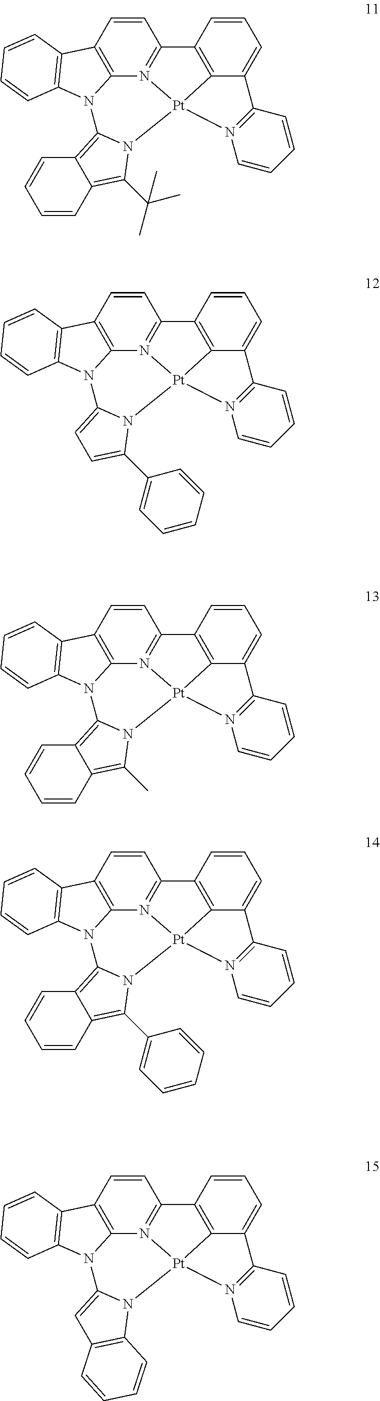

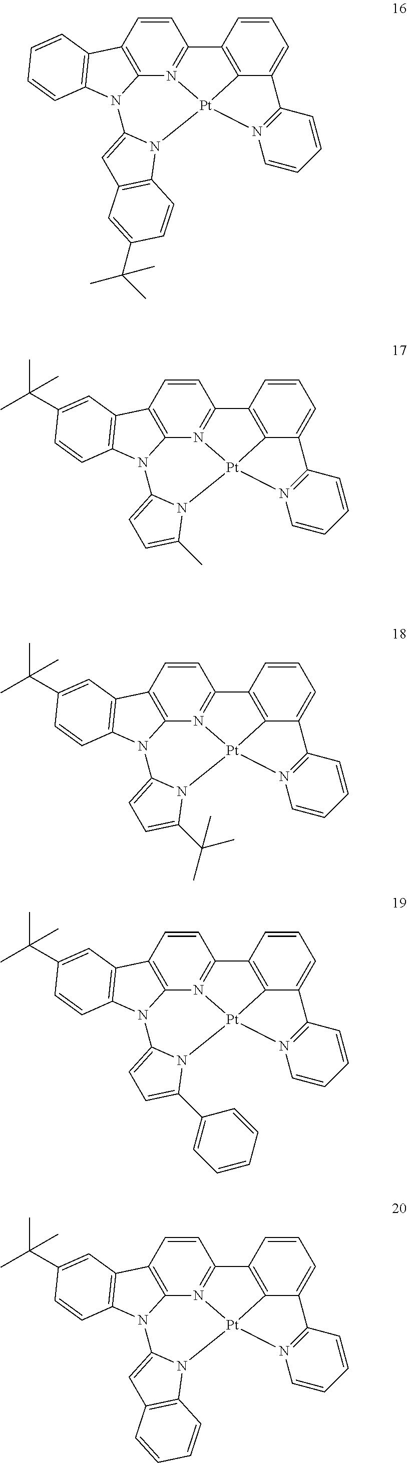

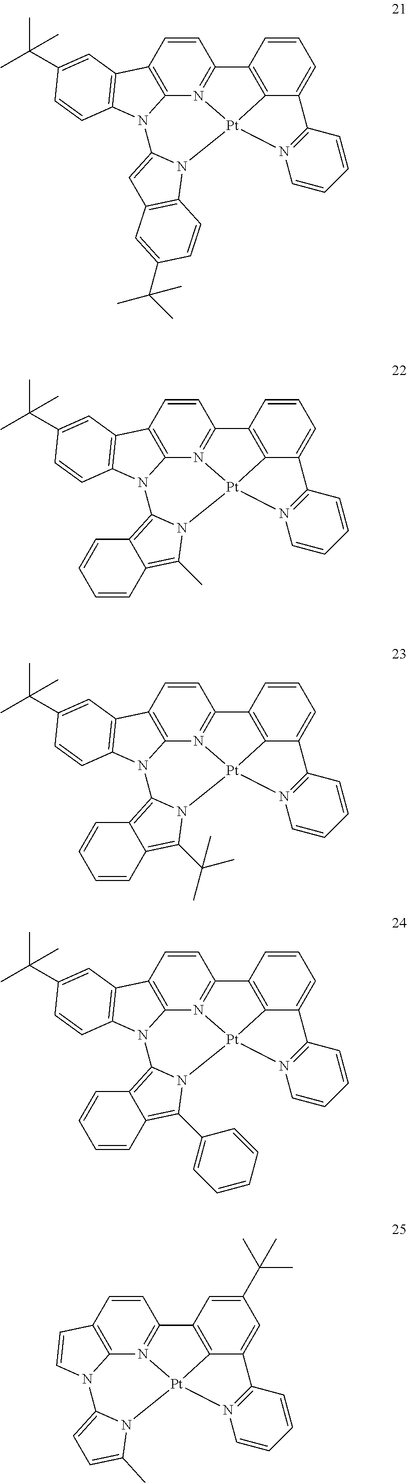

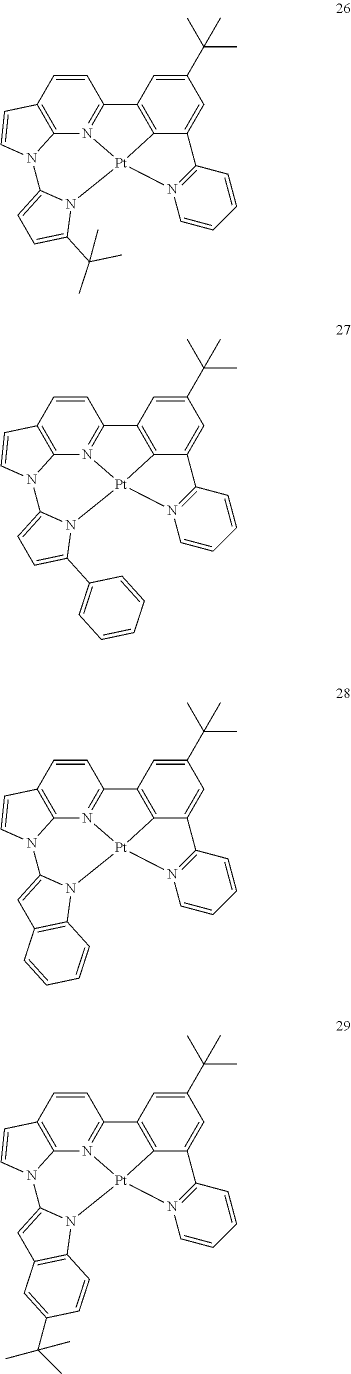

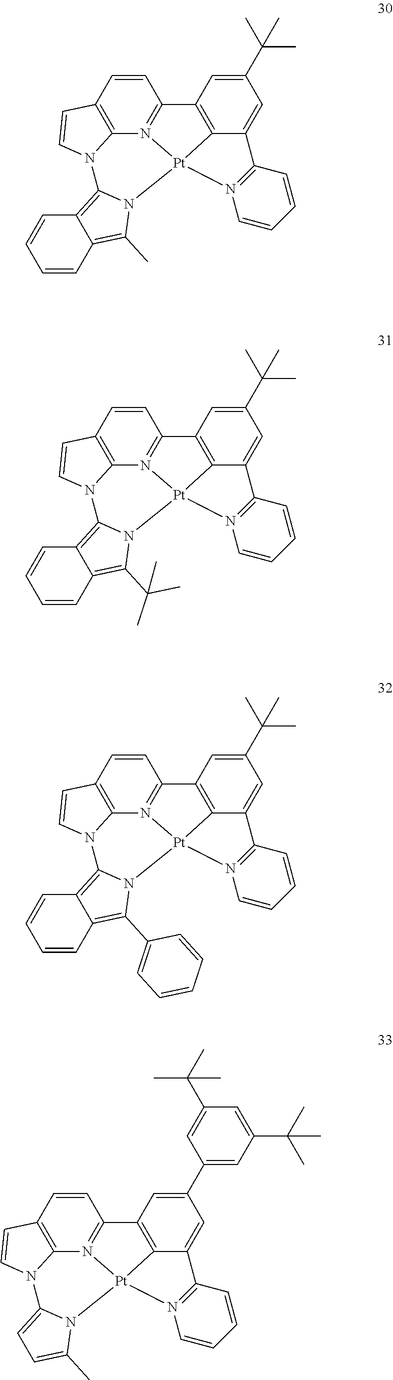

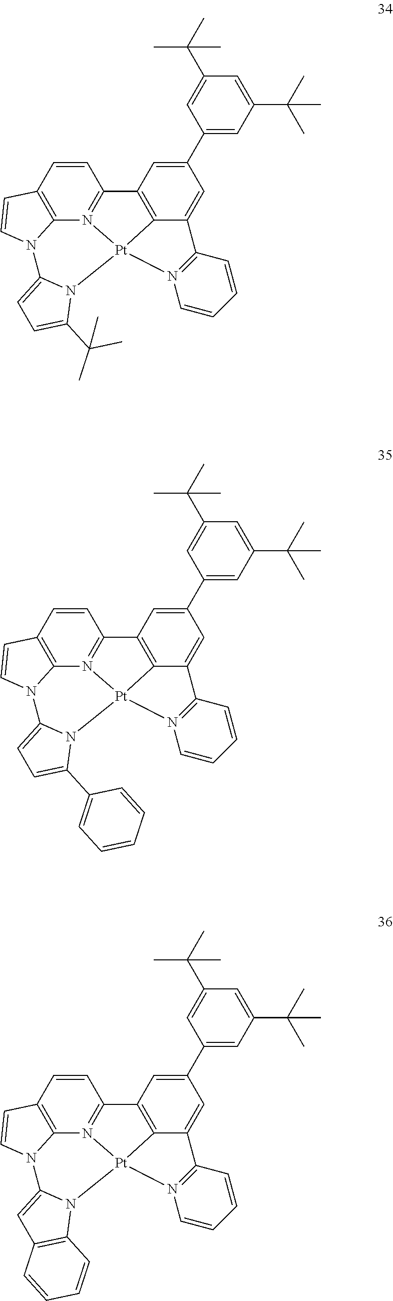

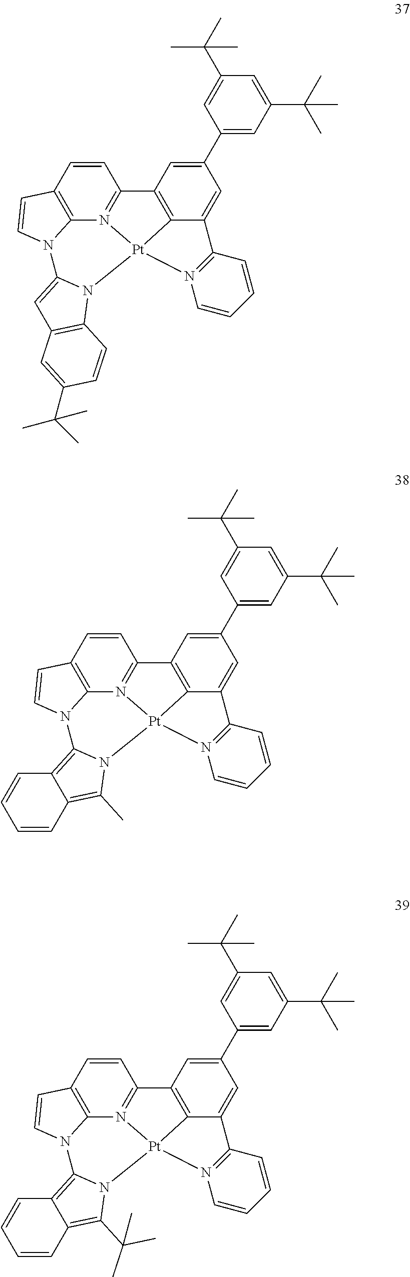

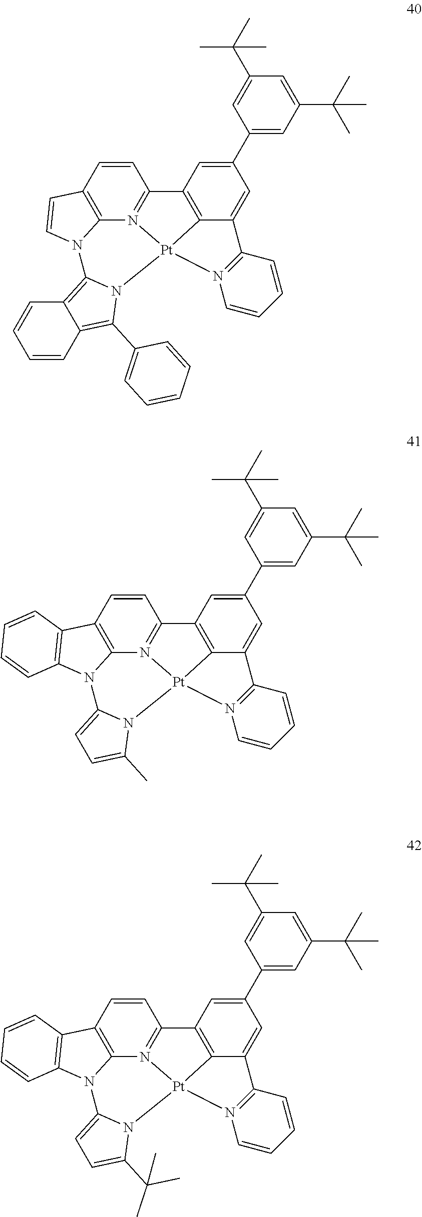

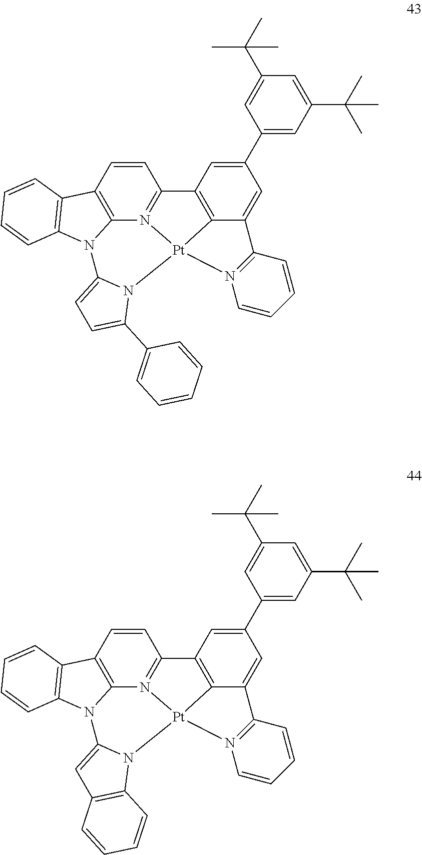

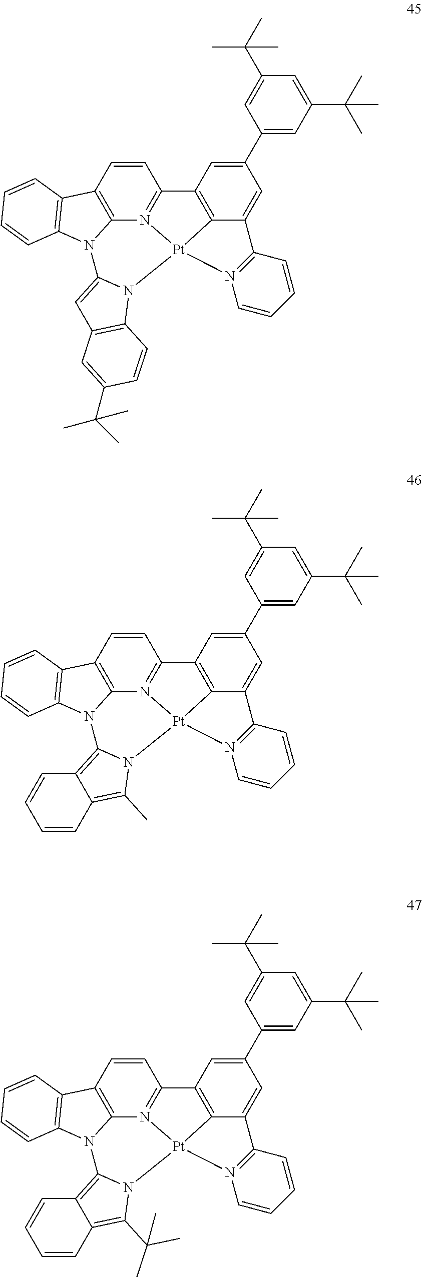

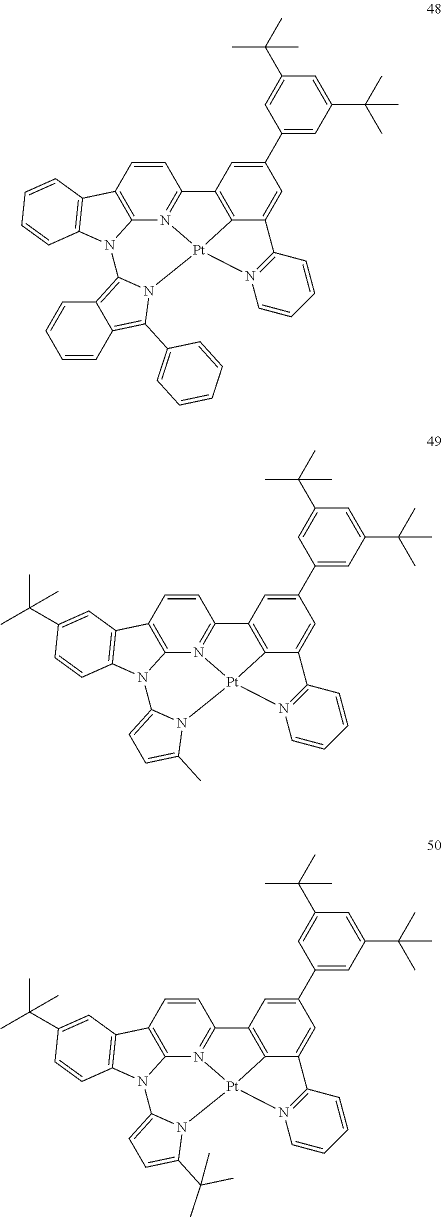

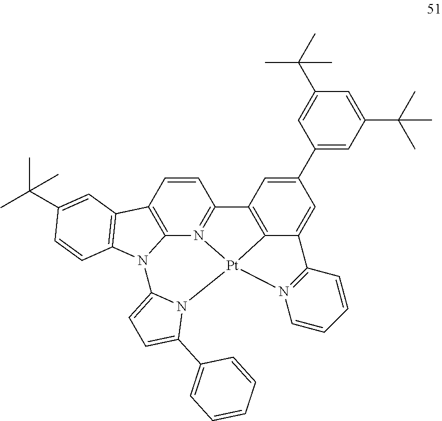

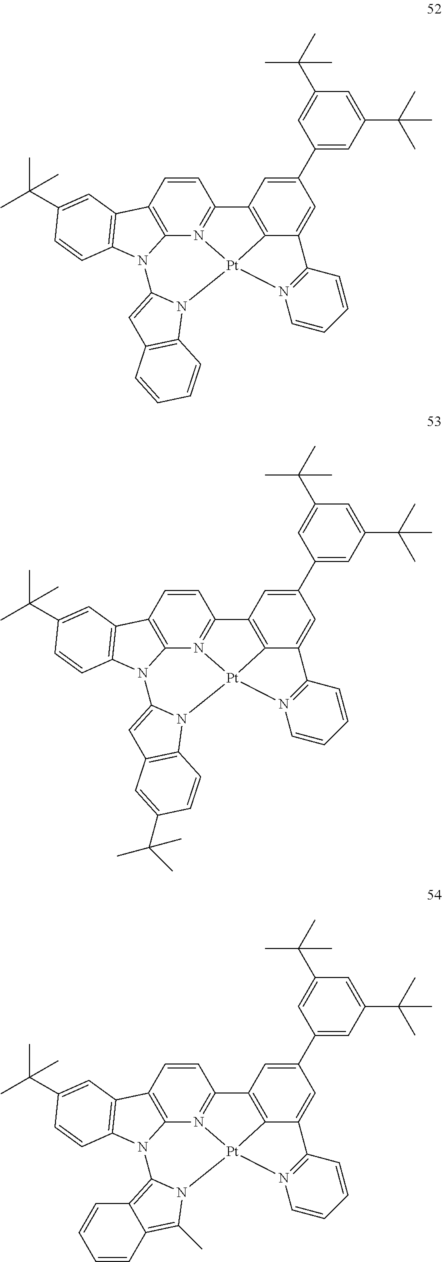

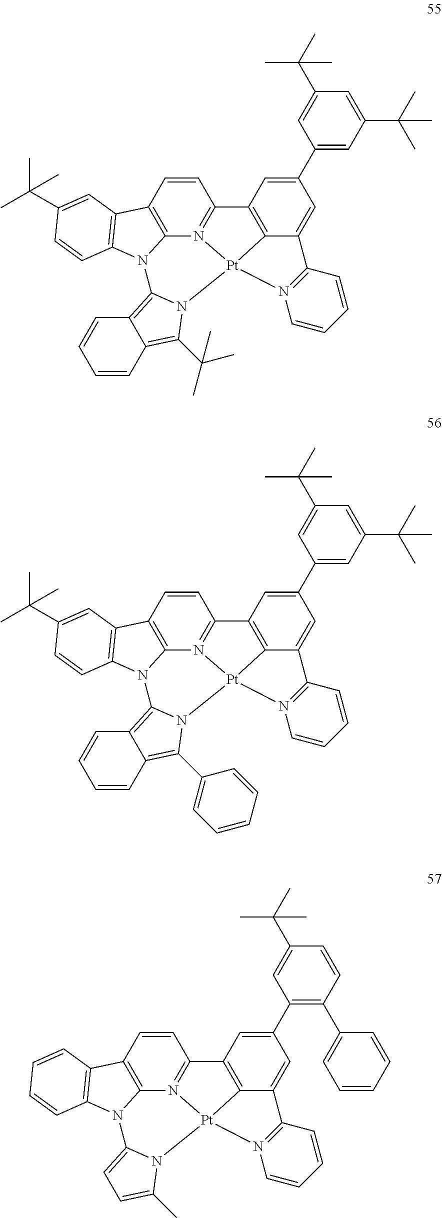

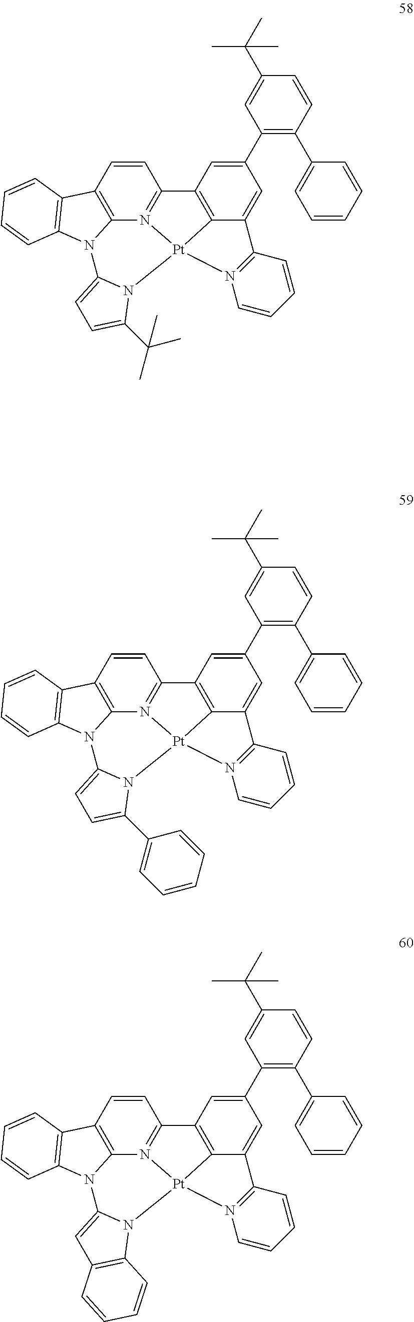

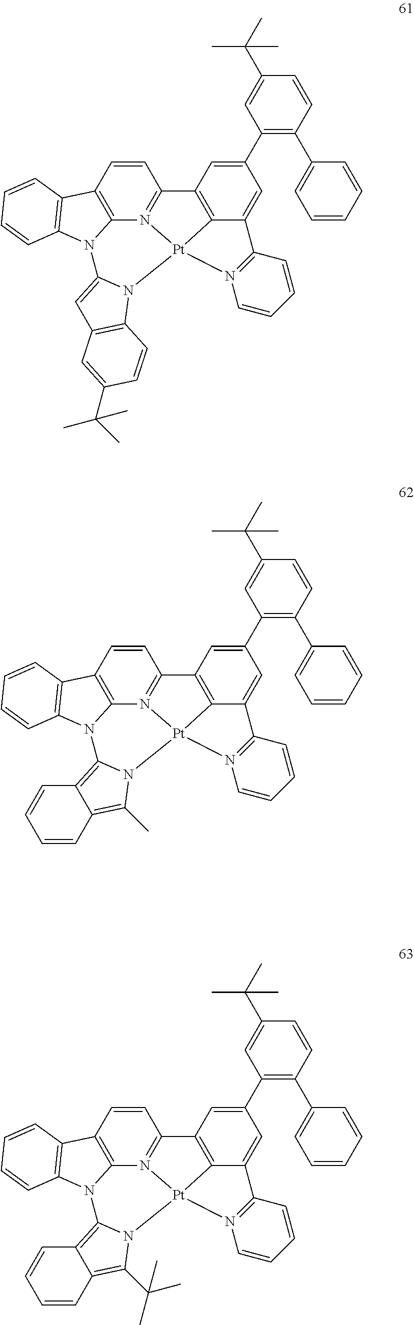

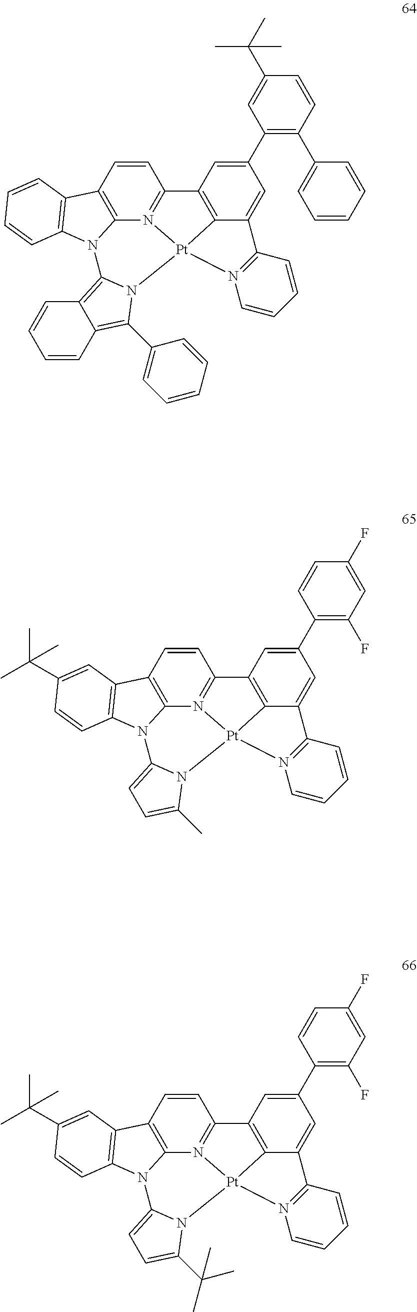

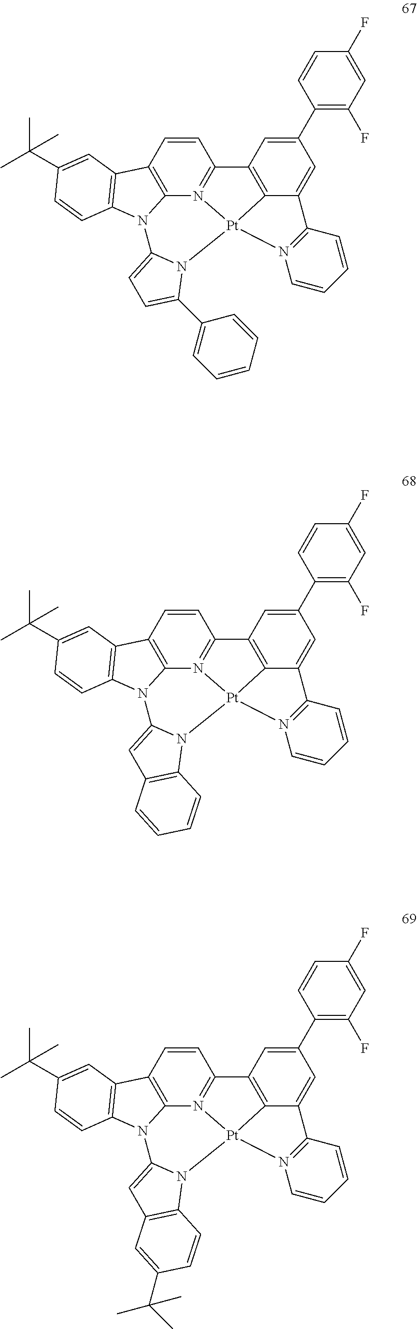

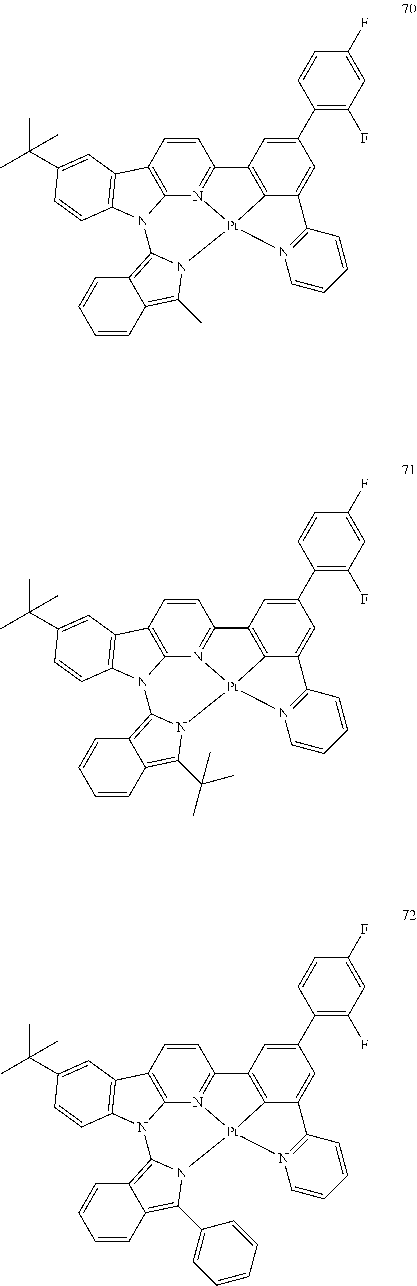

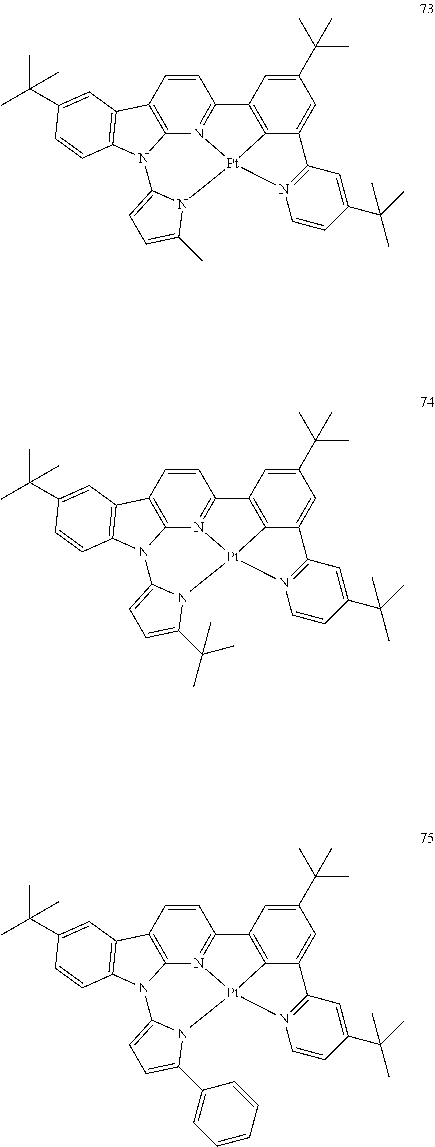

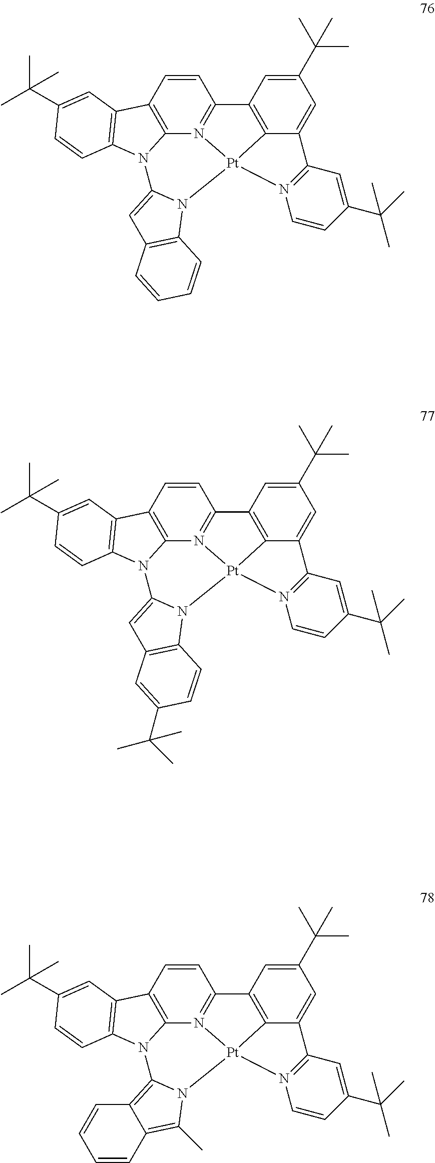

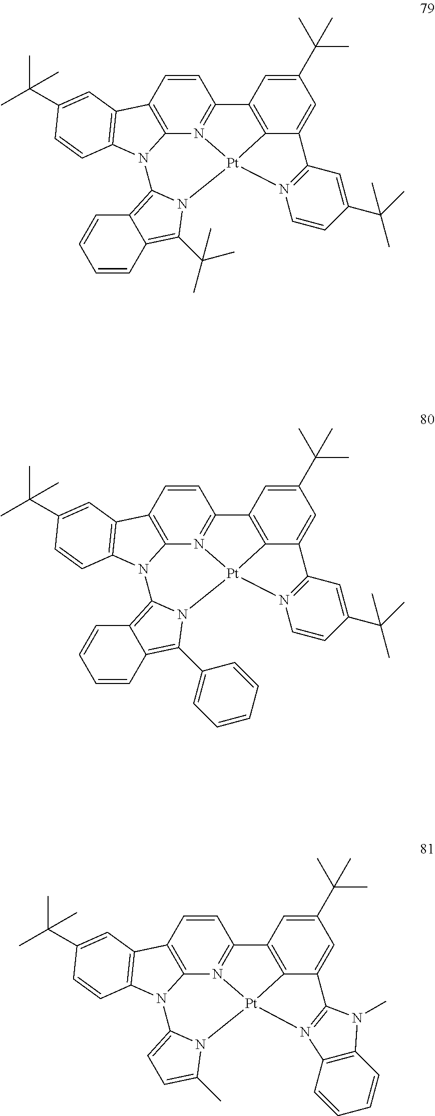

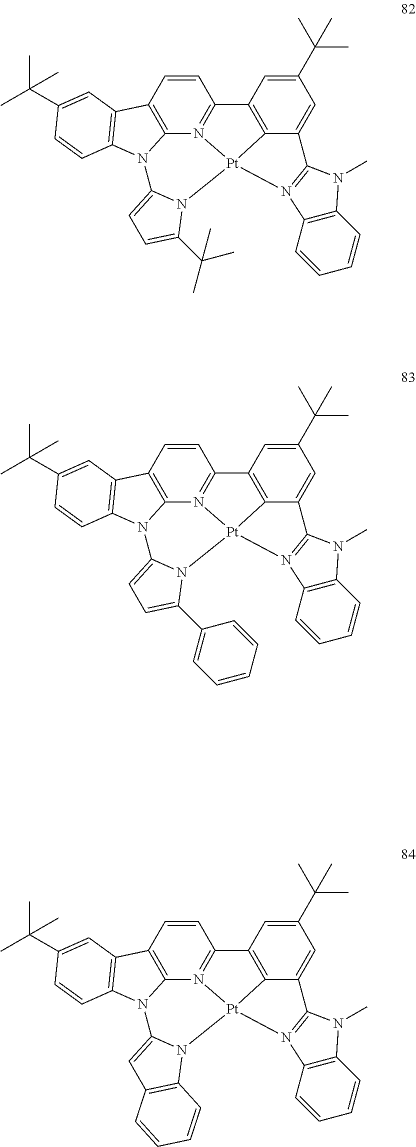

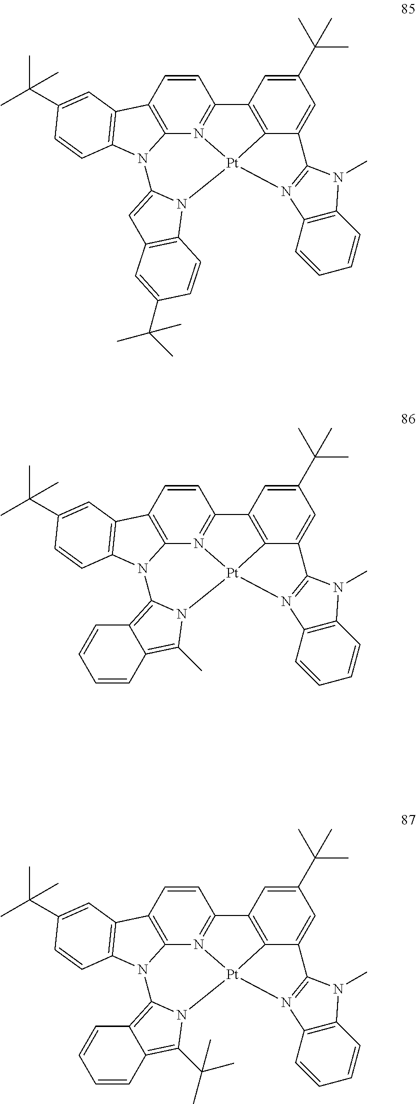

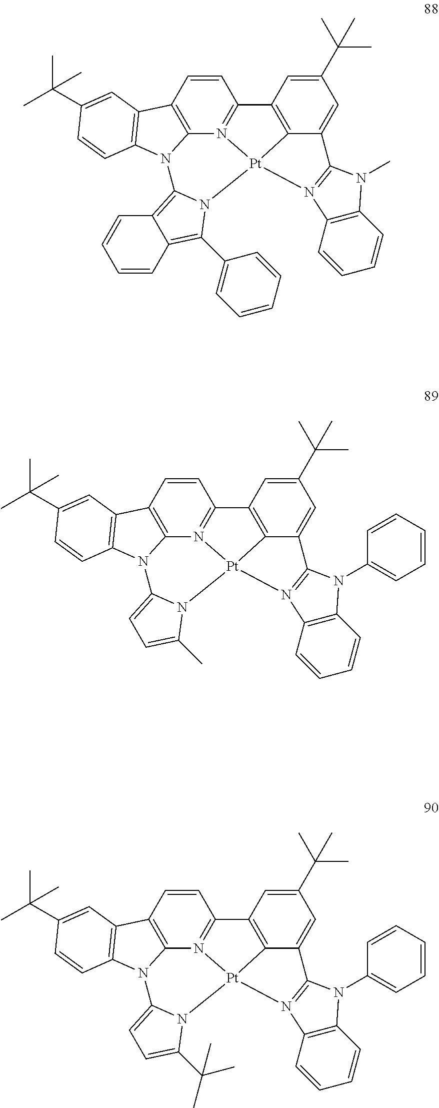

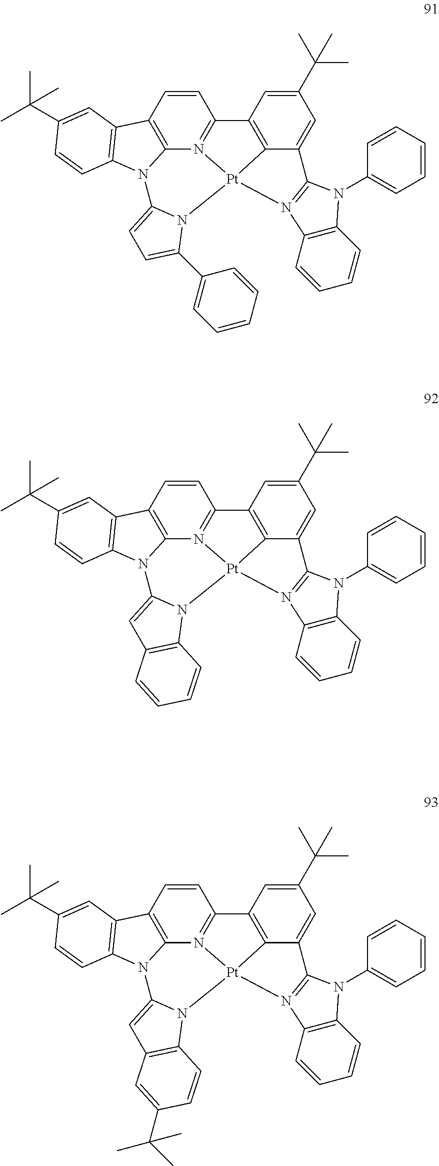

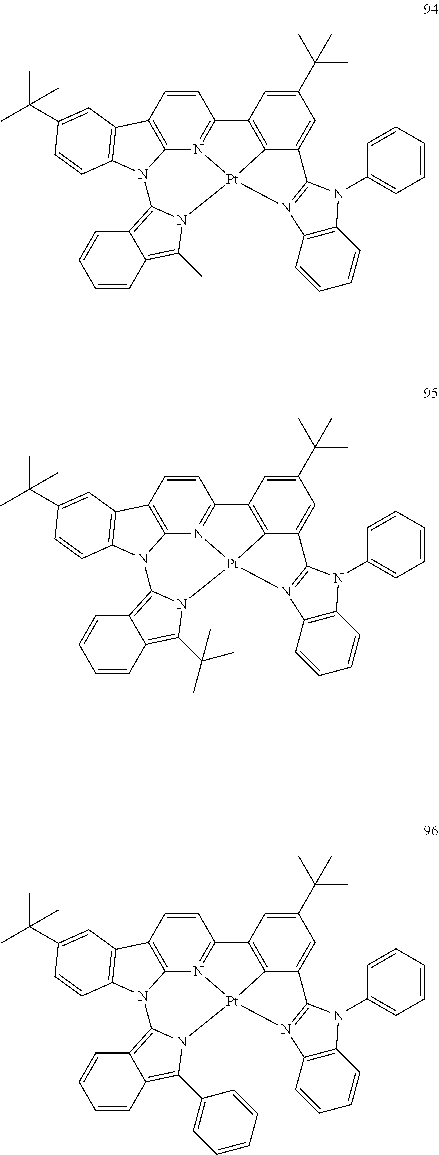

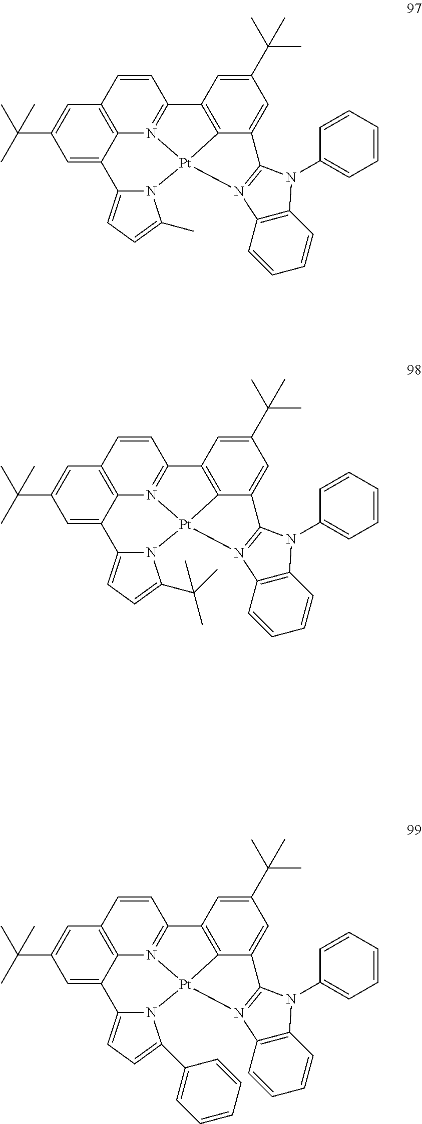

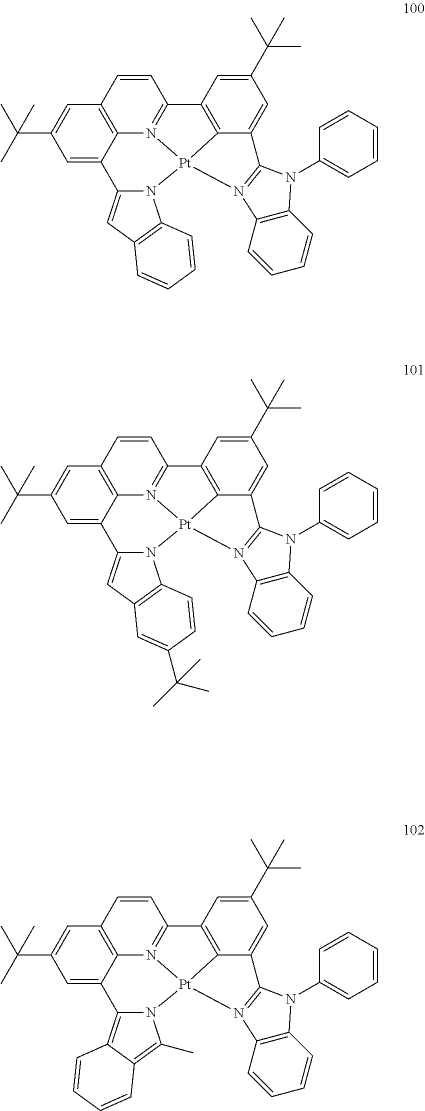

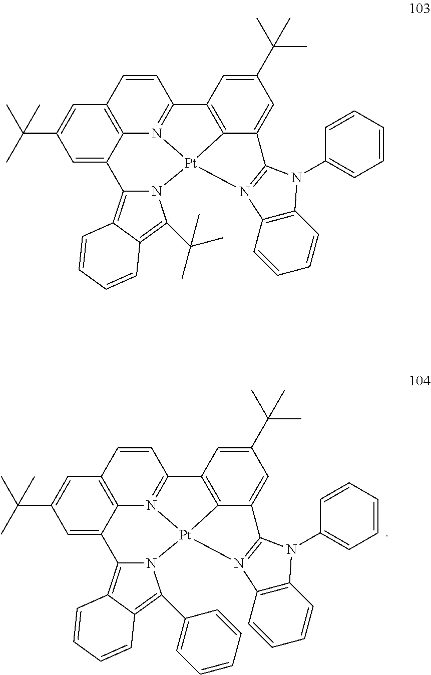

A precursor of the platinum complex, wherein the precursor is a ligand, as shown in a formula as below:

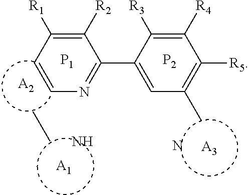

The pressure disclosure further provides uses of the platinum complex described above in organic photoelectronic devices. The organic photoelectronic devices include but are not limited to organic light emitting diodes, organic thin-film transistors, organic photovoltaic devices, light emitting electrochemical cells and chemical sensors. In some embodiments, the organic photoelectronic device is organic light emitting diode.

An organic light emitting diodes in the present disclosure includes a cathode, an anode and an organic layer. The organic layer is selected from the group consisting of an electron hole injection layer, an electron hole transport layer, a luminescent layer, an electron hole blocking layer, an electron injection layer, an electron transport layer, and any combination thereof. The organic layer does not need to include all of the layers. At least one of the electron hole injection layer, the electron hole transport layer, the electron hole blocking layer, the electron injection layer, the luminescent layer and the electron transport layer includes the platinum complex as shown in formal (I).

In some embodiments, the luminescent layer or the electron transport layer includes the platinum complex as shown in formula (I).

In the present disclosure, a total thickness of the organic layer of the device is in a range of 1 nm to 1000 nm. In some embodiments, the total thickness of the organic layer of the device is in a range of 1 nm to 500 nm. In some embodiments, the total thickness of the organic layer of the device is in a range of 5 nm to 300 nm.

The organic layer can be thin films obtained by method of evaporation method or solution method.

The luminescent materials made of platinum complex disclosed in the present disclosure has good luminescence performances, and can be used in organic light emitting diodes as the luminescent materials.

### BRIEF DESCRIPTION OF THE DRAWING

The FIGURE is a schematic diagram of an organic light emitting diode device of the present disclosure.

In the FIGURE, 10 represents a glass substrate, 20 represents an anode, 30 represents an electron hole injection layer, 40 represents an electron hole transport layer, 50 represents a luminescent layer, 60 represents an electron transport layer, 70 represents an electron injection layer, 80 represents a cathode.

### DETAILED DESCRIPTION

The present disclosure does not limit a method of synthesizing the materials, and the following examples are given for the purpose of describing the disclosure in greater detail, but are not limited thereto. The raw materials used in the following syntheses are commercially available if not otherwise noted (2d, 2f, 10a, 20a, 20c, 98c and 98e are ordered products).

### First Embodiment: Synthesis of Complex 2

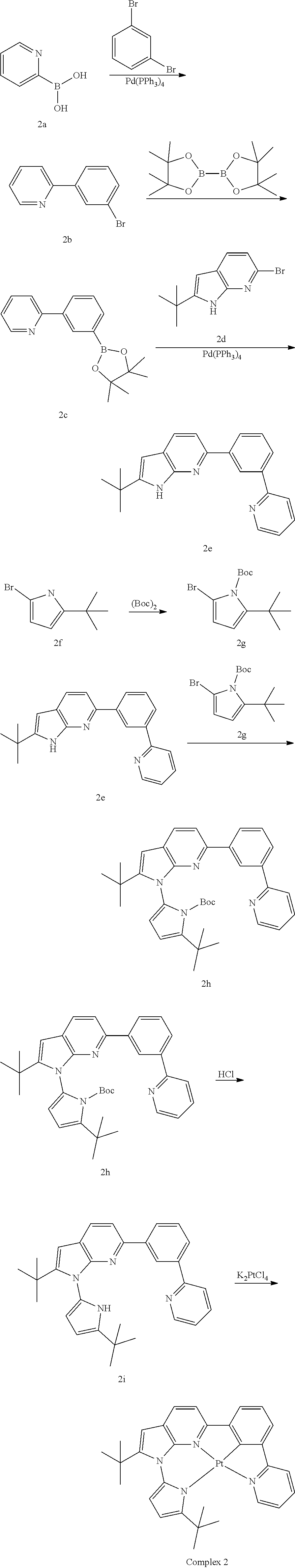

### Synthesis of Complex 2b

2a (10.0 g, 81.3 mmol, 1e.q.), m-dibromobenzene (28.8 g, 122.0 mmol, 1.5 e.q.), tetrakis(triphenylphosphine) palladium (1.39 g, 1.87 mmol, 0.02 e.q.), a potassium carbonate solution (2M, 101.6 mL, 2.5e.q.) and methylbenzene (500 mL) were added into a three-neck flask under nitrogen protection. The reaction system was subjected to a vacuum process and nitrogen was injected into the reaction system, and the processes repeated for three times. Then the reaction mixture was heated until the reaction mixture refluxed, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 14.9 g of white solid was obtained, and a productive rate was 76.5%.

¹H NMR (500 MHz, Chloroform-d) δ 8.78 (dd, J=4.1, 1.5 Hz, 1H), 7.97 (t, J=1.9 Hz, 1H), 7.91 (ddd, J=8.4, 1.8, 1.1 Hz, 1H), 7.72-7.63 (m, 2H), 7.55 (ddd, J=8.1, 2.0, 1.3 Hz, 1H), 7.40-7.34 (m, 1H), 7.27-7.21 (m, 1H).

### Synthesis of Complex 2c

2b (14.0 g, 59.8 mmol, 1 e.q), bis(pinacolato)diboron (22.78 g, 89.7 mmol, 1.5 e.q.), potassium acetate (17.6 g, 179.4 mmol, 3 e.q.), Pd(dppf)₂Cl₂ (0.83 g, 1.19 mmol, 0.02 e.q.) and methylbenzene (500 ml) were added into a flask. The reaction mixture was stirred at room temperature for 30 minutes, heated to 80° C., stirred and reacted for 6 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, dried with anhydrous sodium sulfate, and then subjected to a reduced pressure distillation process to evaporate and remove the solvent. The resultant was separated with silica gel chromatographic column chromatography method, 10.92 g of light yellow grease was obtained, and the productive rate was 65%.

¹H NMR (500 MHz, Chloroform-d) δ 8.78 (dd, J=4.1, 1.6 Hz, 1H), 8.06 (t, J 1.9 Hz, 1H), 7.74 (dddd, J=14.6, 7.1, 2.0, 1.2 Hz, 2H), 7.71-7.63 (m, 2H), 7.45 (dd, J=7.7, 7.1 Hz, 1H), 7.24 (ddd, J=6.3, 4.0, 2.1 Hz, 1H), 1.24 (s, 12H).

### Synthesis of Complex 2e

2c (10 g, 45.8 mmol, 1.5 e.q.), 2d (7.7 g, 30.6 mmol, 1 e.q.), tetrakis(triphenylphosphine) palladium (0.7 g, 0.61 mmol, 0.02e.q.), potassium carbonate solution (2M, 45.9 mL, 3.0 e.q.) and methylbenzene (250 mL) were added into a three-neck flask under nitrogen protection. The reaction system was subjected to a vacuum process and nitrogen was injected into the reaction system, and the processes repeated for three times. Then the reaction mixture was heated until the reaction mixture refluxed, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 6.35 g of white solid was obtained, and the productive rate was 63.4%.

¹H NMR (500 MHz, Chloroform-d) δ 9.56 (s, 1H), 8.78 (dd, J=4.1, 1.6 Hz, 1H), 8.29-8.23 (m, 2H), 7.92 (ddd, J=8.4, 1.8, 1.1 Hz, 1H), 7.89-7.81 (m, 2H), 7.72-7.61 (m, 3H), 7.24 (ddd, J=6.6, 4.0, 1.8 Hz, 1H), 6.54 (d, J=1.9 Hz, 1H). 1.36 (s, 9H).

### Synthesis of Complex 2 g

(Boc)₂O, (6.5 g, 29.9 mmol, 1.2 e.q.) and 4-(dimethylamino)pyridine (0.46 g, 3.73 mmol, 0.15 e.q.) were added into a acetonitrile (50 mL) solution of 2f (5.0 g, 24.9 mmol, 1. e.q.) under nitrogen protection. After the addition process, the mixture was stirred for two hours at room temperature. The mixture was subjected to a reduced pressure distillation process to evaporate and remove the solvent, and the resultant was separated with silica gel chromatographic column chromatography (Al₂O₃) method, 7.15 g of colorless liquid was obtained, and the productive rate was 95.0%.

¹H NMR (500 MHz, Chloroform-d) δ 6.74 (d, J=6.6 Hz, 1H), 5.83 (d, J=6.8 Hz, 1H), 1.61 (s, 9H), 1.36 (s, 9H).

### Synthesis of Complex 2h

2e (5.0 g, 15.3 mmol, 1.e.q), 2 g (6.9 g, 22.9 mmol, 1.5e.q.), potassium carbonate (6.3 g, 45.9 mmol, 3 e.q.), Pd₂(dba)₃ (0.18 g, 0.31 mmol, 0.02 e.q.) and Xphos (0.21 g, 0.31 mmol, 0.02 e.q.) were added into methylbenzene (250 ml) in a flask. The mixture was heated to 80° C., stirred and reacted for 8 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, dried with anhydrous sodium sulfate, and subjected to a reduced pressure distillation process to evaporate and remove the solvent. The resultant was separated with silica gel chromatographic column chromatography method, 4.0 g of white solid was obtained, and the productive rate was 47.8%.

¹H NMR (500 MHz, Chloroform-d) δ 8.78 (dd, J=4.1, 1.6 Hz, 1H), 8.26 (dd, J 7.3, 1.8 Hz, 1H), 8.18 (t, J=1.9 Hz, 1H), 7.95-7.80 (m, 3H), 7.72-7.63 (m, 2H), 7.59 (t, J 8.6 Hz, 1H), 7.24 (ddd, J=6.6, 4.0, 1.8 Hz, 1H), 6.20 (d, J=6.8 Hz, 1H), 6.04 (d, J=2.0 Hz, 1H), 5.94 (d, J=6.8 Hz, 1H), 1.61 (s, 9H), 1.43 (s, 9H), 1.35 (s, 9H).

### Synthesis of Complex 2i

2h (4.0 g, 7.3 mmol) was dissolved in dichloromethane (200 mL), and then hydrochloric acid (0.1M) was added to adjust the pH value of the mixture to 1. The mixture was stirred for 30 minutes, and the solid was filtrated out. The obtained solid was pulped with methanol, filtrated, and potassium carbonate (0.2 M) was added to adjust the pH value of the mixture to a range of 7 to 8. The resultant was extracted with ethyl acetate. The organic phase was concentrated to obtain 3.0 g of light yellow solid, and the productive rate was 91.7%.

¹H NMR (500 MHz, Chloroform-d) δ 8.78 (dd, J=4.1, 1.6 Hz, 1H), 8.41 (s, 1H), 8.28 (dd, J=7.4, 1.9 Hz, 1H), 8.18 (t, J=1.9 Hz, 1H), 7.92 (ddd, J=8.6, 1.9, 1.2 Hz, 1H), 7.89-7.83 (m, 2H), 7.72-7.63 (m, 2H), 7.59 (t, J=8.6 Hz, 1H), 7.24 (ddd, J=6.6, 4.0, 1.8 Hz, 1H), 6.92 (d, J=6.4 Hz, 1H), 6.38 (d, J=6.4 Hz, 1H), 6.01 (d, J=1.9 Hz, 1H), 1.43 (s, 9H), 1.34 (s, 9H).

### Synthesis of Complex 2

2i (2.5 g, 5.57 mmol, 1 e.q.), potassium tetrachloroplatinate (2.51 g, 6.68 mmol, 1.2 e.q.), and tetrabytylammonium bromide (50 mg) were dissolved in acetic acid (250 mL) in a 250 mL single-neck flask. Under nitrogen protection, the mixture was stirred and reacted at 135° C. for 24 hours. After the mixture was cooled to room temperature, water was added in the reaction mixture to separate a solid out, and the resultant was filtrated to obtain a crude product. The crude product was recrystallization with dichloromethane/n-hexane (1/1) to obtain 2.0 g of orange red powder, and the productive rate was 56%.

¹H NMR (500 MHz, Chloroform-d) δ 8.94 (dd, J=5.3, 1.5 Hz, 1H), 7.93-7.84 (m, 2H), 7.77 (dd, J=7.6, 1.9 Hz, 1H), 7.63-7.53 (m, 3H), 7.41 (t, J=7.9 Hz, 1H), 7.26 (ddd, J=7.7, 5.5, 1.4 Hz, 1H), 6.40 (d, J=5.7 Hz, 1H), 6.14 (d, J=5.7 Hz, 1H), 5.64 (d, J=2.0 Hz, 1H), 1.45 (s, 9H), 1.37 (s, 9H).

¹³C NMR (125 MHz, Common NMR Solvents) δ 151.43, 150.99, 147.23, 143.92, 143.42, 142.57, 140.70, 134.03, 132.32, 132.28, 131.83, 130.22, 127.24, 127.22, 126.37, 124.61, 123.55, 117.74, 109.83, 108.81, 100.58, 40.49, 40.20, 30.02, 30.01, 30.00, 29.87.

ESI-HRMS (m/z): 642.212 (M+1).

### Second Embodiment: Synthesis of Complex 10

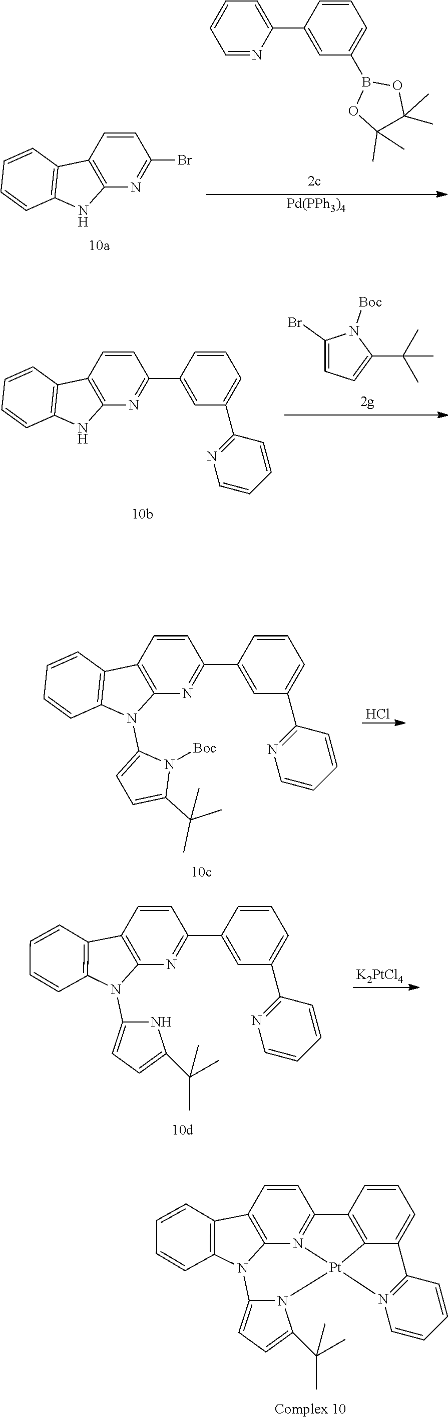

### Synthesis of Complex 10b

10a (8 g, 40.5 mmol, 1 e.q.), 2c (17.1 g, 60.7 mmol, 1.5 e.q.), tetrakis(triphenylphosphine) palladium (0.93 g, 0.81 mmol, 0.02 e.q.), potassium carbonate solution (2 M, 60.7 mL, 3.0 e.q.) and methylbenzene (300 mL) were added in a three-neck flask under nitrogen protection. The reaction system was subjected to a vacuum process and nitrogen was injected into the reaction system, and the processes repeated for three times. Then the reaction mixture was heated to 80° C. and refluxed, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 8.41 g of white solid was obtained, and the productive rate was 64.6%.

¹H NMR (500 MHz, Chloroform-d) δ 8.78 (dd, J=4.1, 1.6 Hz, 1H), 8.37 (d, J=8.0 Hz, 1H), 8.27 (t, J=2.0 Hz, 1H), 8.12-8.06 (m, 1H), 7.92 (ddd, J=8.4, 1.8, 1.1 Hz, 1H), 7.89-7.83 (m, 2H), 7.72-7.61 (m, 3H), 7.49 (dd, J=7.5, 2.0 Hz, 1H), 7.37 (td, J=7.4, 1.3 Hz, 1H), 7.28-7.21 (m, 2H).

### Synthesis of Complex 10c

10b (8.0 g, 24.9 mmol, 1.e.q), 2 g (11.3 g, 37.35 mmol, 1.5 e.q.), potassium carbonate (10.3 g, 74.7 mmol, 3 e.q.), Pd₂(dba)₃ (0.29 g, 0.50 mmol, 0.02 e.q.) and Xphos (0.33 g, 0.50 mmol, 0.02 e.q.) were added into methylbenzene (250 ml), and added in a flask. The mixture was heated to 80° C., stirred and reacted for 8 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, and dried with anhydrous sodium sulfate. The mixture was subjected to a reduced pressure distillation process to evaporate and remove the solvent. The resultant was separated with silica gel chromatographic column chromatography method, 6.2 g of white solid was obtained, the productive rate was 46.2%.

¹H NMR (500 MHz, Chloroform-d) δ 8.78 (dd, J=4.1, 1.6 Hz, 1H), 8.45 (d, J=7.6 Hz, 1H), 8.18 (t, J=2.0 Hz, 1H), 8.12 (dd, J=7.7, 1.2 Hz, 1H), 7.92 (ddd, J=8.6, 1.9, 1.2 Hz, 1H), 7.89-7.83 (m, 2H), 7.72-7.63 (m, 3H), 7.59 (t, J=8.6 Hz, 1H), 7.41-7.34 (m, 1H), 7.32-7.21 (m, 2H), 6.30 (d, J=6.8 Hz, 1H), 5.97 (d, J=6.8 Hz, 1H), 1.61 (s, 9H), 1.35 (s, 9H).

### Synthesis of Complex 10d

10c (6.0 g, 11.1 mmol) was dissolved in dichloromethane (250 mL), and then hydrochloric acid (0.1 M) was added to adjust the pH value of the mixture to 1. The mixture was stirred for 30 minutes, and the solid was filtrated out. The obtained solid was pulped with methanol, filtrated, and potassium carbonate (0.2 M) was added to adjust the pH value of the mixture to a range of 7 to 8, and extracted with ethyl acetate. The organic phase was concentrated to obtain 4.89 g of light yellow solid, and the productive rate was 89.4%.

¹H NMR (500 MHz, Chloroform-d) δ 9.70 (s, 1H), 8.78 (dd, J=4.1, 1.6 Hz, 1H), 8.47 (d, J=7.6 Hz, 1H), 8.20-8.14 (m, 2H), 7.95-7.84 (m, 3H), 7.72-7.63 (m, 3H), 7.59 (t, J=8.6 Hz, 1H), 7.41-7.35 (m, 1H), 7.29 (ddd, J=8.2, 7.1, 1.3 Hz, 1H), 7.24 (ddd, J=6.6, 4.0, 1.8 Hz, 1H), 7.02 (d, J=6.4 Hz, 1H), 6.40 (d, J=6.2 Hz, 1H), 1.34 (s, 9H).

### Synthesis of Complex 10

10d (4.50 g, 10.2 mmol, 1 e.q.), potassium tetrachloroplatinate (4.60 g, 12.24 mmol, 1.2 e.q.) and tetrabytylammonium bromide (90 mg) were dissolved in acetic acid (150 mL) in a 250 mL single-neck flask. Under nitrogen protection, the mixture was stirred and reacted at 135° C. for 24 hours. After the mixture was cooled to room temperature, water was added in the reaction mixture to separate a solid out, and the resultant was filtrated to obtain a crude product. The crude product was recrystallization with dichloromethane/n-hexane (1/1) to obtain 3.31 g of orange red powder, and the productive rate was 51%.

¹H NMR (500 MHz, Chloroform-d) δ 8.98-8.93 (m, 1H), 8.09-8.04 (m, 1H), 7.96 (d, J=7.8 Hz, 1H), 7.93-7.87 (m, 2H), 7.71 (dd, J=6.2, 1.5 Hz, 1H), 7.63-7.53 (m, 3H), 7.41 (t, J=7.9 Hz, 1H), 7.37-7.23 (m, 3H), 6.84 (d, J=5.7 Hz, 1H), 6.17 (d, J=5.7 Hz, 1H), 1.37 (s, 9H).

¹³C NMR (125 MHz, Common NMR Solvents) δ 151.43, 151.23, 147.23, 143.94, 142.67, 136.92, 135.82, 134.57, 134.05, 132.32, 132.28, 129.55, 127.24, 127.22, 127.14, 124.61, 123.75, 123.55, 121.33, 119.84, 115.88, 110.19, 109.05, 100.37, 40.20, 29.87.

ESI-HRMS (m/z): 636.165 (M+1).

### Embodiment 3: Synthesis of Complex 20

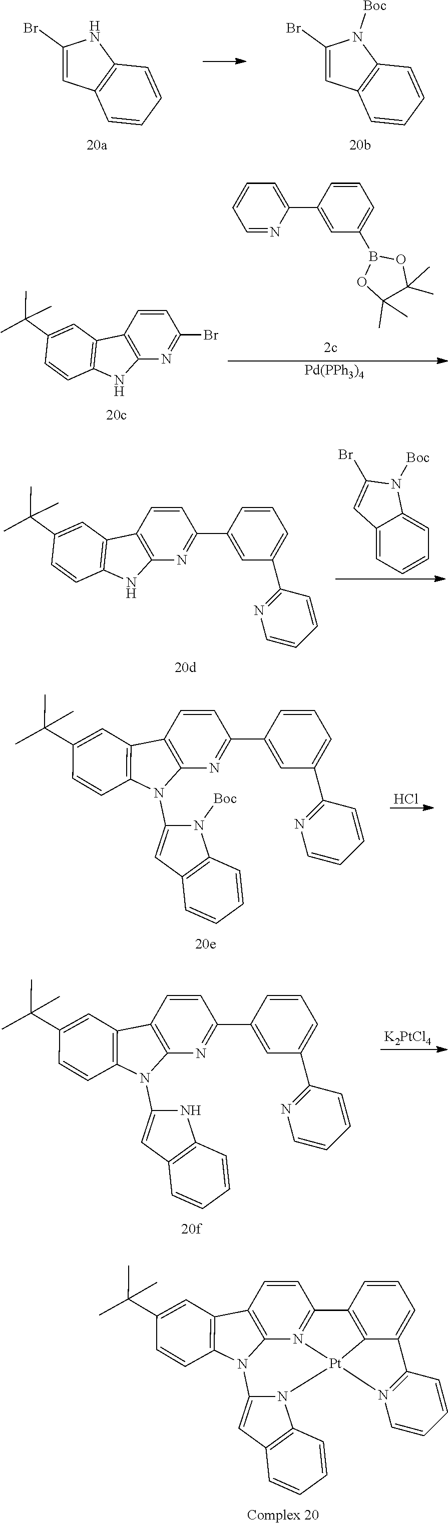

### Synthesis of Complex 20b

(Boc)₂O, (13.37 g, 61.2 mmol, 1.2 e.q.) and 4-(dimethylamino) pyridine (0.93 g, 7.65 mmol, 0.15 e.q.) were added into an acetonitrile solution (200 mL) of 20a (10.0 g, 51.0 mmol, 1.0.e.q.). After the addition process accomplished, the mixture was stirred at room temperature for two hours. The mixture was subjected to a reduced pressure distillation process to evaporate and remove the solvent. The resultant was separated with silica gel chromatographic column chromatography (Al₂O₃) method, 14.1 g of colorless liquid was obtained, and the productive rate was 93.1%.

¹H NMR (500 MHz, Chloroform-d) δ 7.94-7.88 (m, 2H), 7.49 (ddd, J=8.4, 6.6, 1.0 Hz, 1H), 7.14 (td, J=6.8, 1.3 Hz, 1H), 6.50 (d, J=1.9 Hz, 1H), 1.61 (s, 9H).

### Synthesis of Complex 20d

20c (5 g, 16.5 mmol, 1 e.q.), 2c (6.95 g, 24.7 mmol, 1.5 e.q.), tetrakis(triphenylphosphine) palladium (0.38 g, 0.33 mmol, 0.02 e.q.), potassium carbonate solution (2 M, 24.7 mL, 3.0 e.q.) and methylbenzene (200 mL) were added into a three-neck flask under nitrogen protection. The reaction system was subjected to a vacuum process and nitrogen was injected into the reaction system, and the processes repeated for three times. Then the reaction mixture was heated until the reaction mixture refluxed, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 3.86 g of white solid was obtained, and the productive rate was 62%.

¹H NMR (500 MHz, Chloroform-d) δ 8.78 (dd, J=4.1, 1.6 Hz, 1H), 8.39 (d, J=8.0 Hz, 1H), 8.27 (t, J=1.9 Hz, 1H), 8.16 (dt, J=1.6, 0.8 Hz, 1H), 7.95-7.84 (m, 3H), 7.72-7.61 (m, 3H), 7.38-7.31 (m, 2H), 7.24 (ddd, J=6.6, 4.0, 1.8 Hz, 1H), 1.35 (s, 9H).

### Synthesis of Complex 20e

20d (3.5 g, 9.27 mmol, 1.e.q), 20b (4.12 g, 13.9 mmol, 1.5 e.q.), potassium carbonate (3.84 g, 27.8 mmol, 3 e.q.), Pd₂(dba)₃ (0.11 g, 0.19 mmol, 0.02 e.q.) and Xphos (0.12 g, 0.19 mmol, 0.02 e.q.) were added into methylbenzene (150 ml) in a flask. The mixture was heated to 80° C., and stirred and reacted for 8 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, and dried with anhydrous sodium sulfate. The mixture was subjected to a reduced pressure distillation process to evaporate and remove the solvent. The resultant was separated with silica gel chromatographic column chromatography method, 2.5 g of white solid was obtained, and the productive rate was 45.6%.

¹H NMR (500 MHz, Chloroform-d) δ 8.78 (dd, J=4.1, 1.6 Hz, 1H), 8.45 (d, J=7.6 Hz, 1H), 8.18 (t, J=1.9 Hz, 1H), 8.07 (d, J=2.1 Hz, 1H), 7.95-7.84 (m, 5H), 7.72-7.64 (m, 2H), 7.62 (d, J=7.7 Hz, 1H), 7.59 (t, J=8.6 Hz, 1H), 7.55-7.48 (m, 1H), 7.29-7.21 (m, 3H), 7.16 (td, J=6.6, 1.3 Hz, 1H), 1.61 (s, 9H), 1.35 (s, 9H).

### Synthesis of Complex 20f

20e (2.0 g, 3.77 mmol) was dissolved in dichloromethane (100 mL), and then hydrochloric acid (0.1 M) was added to adjust the pH value of the mixture to 1. The mixture was stirred for 30 minutes, and the solid was filtrated out. The obtained solid was pulped with methanol, filtrated, and potassium carbonate (0.2 M) was added to adjust the pH value of the mixture to a range of 7 to 8. The resultant was extracted with ethyl acetate. The organic phase was concentrated to obtain 1.67 g of light yellow solid, and the productive rate was 89.8%.

¹H NMR (500 MHz, Chloroform-d) δ 9.69 (s, 1H), 8.78 (dd, J=4.1, 1.6 Hz, 1H), 8.48 (d, J=7.4 Hz, 1H), 8.18 (t, J=1.9 Hz, 1H), 8.11 (d, J=1.8 Hz, 1H), 7.95-7.89 (m, 2H), 7.87 (ddd, J=8.6, 1.9, 1.2 Hz, 1H), 7.72-7.64 (m, 2H), 7.64-7.53 (m, 4H), 7.36 (dd, J=8.0, 1.4 Hz, 1H), 7.30-7.21 (m, 2H), 7.14 (dtd, J=24.5, 7.2, 1.3 Hz, 2H), 1.35 (s, 9H).

### Synthesis of Complex 20

20f (1.5 g, 3.0 mmol), potassium tetrachloroplatinate (1.37 g, 3.6 mmol) and tetrabytylammonium bromide (50 mg) were dissolved in acetic acid (150 mL) in a 250 mL single-neck flask. Under nitrogen protection, the mixture was stirred and reacted at 135° C. for 24 hours. After the mixture was cooled to room temperature, water was added in the reaction mixture to separate a solid out, and the resultant was filtrated to obtain a crude product. The crude product was recrystallization with dichloromethane/n-hexane (1/1) to obtain 1.05 g of orange red powder, and the productive rate was 51.1%.

¹H NMR (500 MHz, Chloroform-d) δ 8.98 (dd, J=5.2, 1.4 Hz, 1H), 8.19 (d, J=8.0 Hz, 1H), 7.94-7.82 (m, 5H), 7.68-7.62 (m, 2H), 7.62-7.53 (m, 3H), 7.41 (t, J=7.9 Hz, 1H), 7.24-7.18 (m, 3H), 7.15 (td, J=7.0, 1.6 Hz, 1H), 1.35 (s, 9H).

¹³C NMR (125 MHz, Common NMR Solvents) δ 151.46, 147.52, 147.27, 145.45, 145.17, 142.96, 141.57, 137.20, 134.82, 134.27, 132.52, 132.32, 129.48, 128.24, 127.28, 127.24, 127.22, 124.79, 124.61, 123.55, 123.21, 121.96, 121.93, 121.79, 117.50, 115.89, 111.84, 109.18, 96.22, 35.99, 31.08.

ESI-HRMS (m/z): 686.681 (M+1).

### Fourth Embodiment: Synthesis of Complex 44

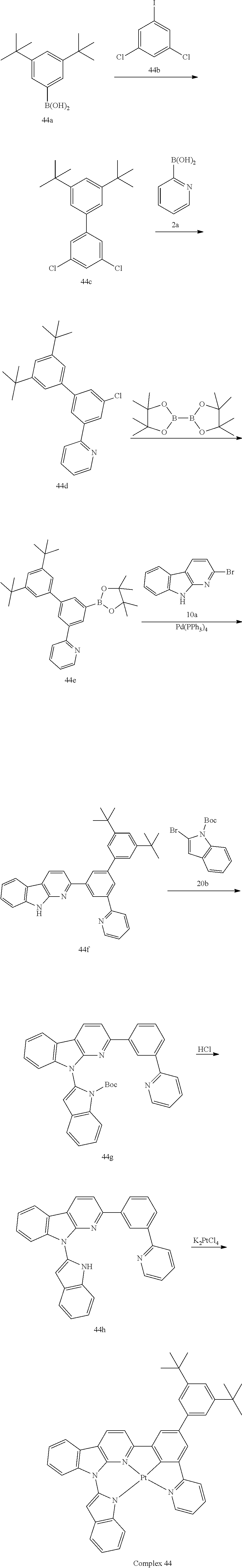

### Synthesis of Complex 44c

44a (10.0 g, 42.7 mmol, 1 e.q.), 44b (13.98 g, 51.2 mmol, 1.2 e.q.), tetrakis(triphenylphosphine) palladium (0.99 g, 0.85 mmol, 0.02 e.q.), potassium carbonate solution (2 M, 53.4 mL, 2.5 e.q.) and tetrahydrofuran (250 mL) were added into a three-neck flask under nitrogen protection. The reaction system was subjected to a vacuum process and nitrogen was injected into the reaction system, and the processes repeated for three times. Then the mixture was heated to 60° C., and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 9.23 g of white solid was obtained, and the productive rate was 64.5%.

¹H NMR (500 MHz, Chloroform-d) δ 7.59 (d, J=2.1 Hz, 2H), 7.50 (t, J=2.2 Hz, 1H), 7.43 (t, J=2.2 Hz, 1H), 7.33 (s, 2H), 1.35 (s, 18H).

### Synthesis of Complex 44d

2a (2.75 g, 22.4 mmol, 1 e.q.), 44c (9 g, 26.8 mmol, 1.2 e.q.), tetrakis(triphenylphosphine) palladium (0.52 g, 0.45 mmol, 0.02 e.q.), potassium carbonate solution (2M, 28 mL, 2.5 e.q.) and tetrahydrofuran (140 mL) were added into a three-neck flask under nitrogen protection. The reaction system was subjected to a vacuum process and nitrogen was injected into the reaction system, and the processes repeated for three times. Then the reaction mixture was heated to 60° C., and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 5.24 g of white solid was obtained, and the productive rate was 62%.

¹H NMR (500 MHz, Chloroform-d) δ 8.78 (dd, J=4.0, 1.6 Hz, 1H), 7.94 (t, J=2.1 Hz, 1H), 7.78 (t, J=2.2 Hz, 1H), 7.73 (dd, J=7.4, 1.5 Hz, 1H), 7.70-7.63 (m, 2H), 7.50 (t, J=2.2 Hz, 1H), 7.38 (s, 2H), 7.24 (ddd, J=7.1, 4.0, 1.6 Hz, 1H), 1.35 (s, 18H).

### Synthesis of Complex 44e

44d (5.0 g, 13.2 mmol, 1.e.q), bis(pinacolato)diboron (5.03 g, 19.8 mmol, 1.5 e.q.), potassium acetate (5.46 g, 39.6 mmol, 3 e.q.), Pd(dppf)₂Cl₂ (0.19 g, 0.26 mmol, 0.02 e.q.) and methylbenzene (200 mL) were added in a flask. The mixture was stirred at room temperature for 30 minutes, heated to 80° C., and stirred and reacted for 6 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, and dried with anhydrous sodium sulfate. The mixture was subjected to a reduced pressure distillation process to evaporate and remove the solvent. The resultant was separated with silica gel chromatographic column chromatography method, 3.67 g of light yellow grease was obtained, and the productive rate was 59.3%.

¹H NMR (500 MHz, Chloroform-d) δ 8.78 (dd, J=4.0, 1.6 Hz, 1H), 8.02 (t, J=2.1 Hz, 1H), 7.86 (t, J=2.2 Hz, 1H), 7.82 (t, J=2.2 Hz, 1H), 7.73 (dd, J=7.3, 1.6 Hz, 1H), 7.66 (td, J=7.3, 1.7 Hz, 1H), 7.50 (t, J=2.2 Hz, 1H), 7.37 (d, J=2.2 Hz, 2H), 7.24 (ddd, J=7.1, 4.1, 1.6 Hz, 1H), 1.35 (s, 18H), 1.24 (s, 12H).

### Synthesis of Complex 44f

10a (1.53 g, 6.21 mmol, 1 e.q.), 44e (3.5 g, 7.45 mmol, 1.2 e.q.), tetrakis(triphenylphosphine) palladium (0.035 g, 0.31 mmol, 0.02 e.q.), potassium carbonate solution (2M, 7.7 mL, 2.5 e.q.) and tetrahydrofuran (50 mL) were added in a three-neck flask under nitrogen protection. The reaction system was subjected to a vacuum process and nitrogen was injected into the reaction system, and the processes repeated for three times. Then the reaction mixture was heated to 60° C., and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 2.12 g of white solid was obtained, and the productive rate was 67.0%.

¹H NMR (500 MHz, Chloroform-d) δ 8.78 (dd, J=4.0, 1.6 Hz, 1H), 8.38 (d, J=8.0 Hz, 1H), 8.18 (t, J=2.2 Hz, 1H), 8.12-8.06 (m, 1H), 7.98 (t, J=2.2 Hz, 1H), 7.94 (t, J=2.2 Hz, 1H), 7.84 (d, J=7.9 Hz, 1H), 7.73 (dd, J=7.4, 1.4 Hz, 1H), 7.67 (td, J=7.3, 1.7 Hz, 1H), 7.52-7.46 (m, 2H), 7.43 (d, J=2.1 Hz, 2H), 7.37 (td, J=7.4, 1.3 Hz, 1H), 7.28-7.21 (m, 2H), 1.35 (s, 18H).

### Synthesis of Complex 44 g

44f (2 g, 3.92 mmol, 1.e.q), 20b (1.74 g, 5.89 mmol, 1.5 e.q.), potassium carbonate (1.62 g, 11.76 mmol, 3 e.q.), Pd₂(dba)₃ (0.045 g, 0.078 mmol, 0.02 e.q.) and Xphos (0.037 g, 0.078 mmol, 0.02 e.q.) were added in methylbenzene (100 mL) in a flask. The mixture was heated to 80° C., and stirred and reacted for 8 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, and dried with anhydrous sodium sulfate. The mixture was subjected to a reduced pressure distillation process to evaporate and remove the solvent. The resultant was separated with silica gel chromatographic column chromatography method, 1.14 g of white solid was obtained, and the productive rate was 54.3%.

### Synthesis of Complex 44h

44 g (1.0 g, 1.86 mmol) was dissolved in dichloromethane (50 mL), and then hydrochloric acid (0.1 M) was added to adjust the pH value of the mixture to 1. The mixture was stirred for 30 minutes, and the solid was filtrated out. The obtained solid was pulped with methanol, filtrated, and potassium carbonate (0.2 M) was added to adjust the pH value of the mixture to a range of 7 to 8. The organic phase was concentrated to obtain 0.78 g of light yellow solid, and the productive rate was 95.6%.

¹H NMR (500 MHz, Chloroform-d) δ 9.71 (s, 1H), 8.78 (dd, J=4.1, 1.6 Hz, 1H), 8.48 (d, J=7.5 Hz, 1H), 8.21-8.16 (m, 2H), 7.92 (ddd, J=8.6, 1.9, 1.2 Hz, 1H), 7.91-7.84 (m, 2H), 7.72-7.63 (m, 3H), 7.62-7.54 (m, 2H), 7.55 (d, J=1.9 Hz, 1H), 7.42-7.34 (m, 2H), 7.29 (ddd, J=8.3, 7.1, 1.3 Hz, 1H), 7.24 (ddd, J=6.6, 4.0, 1.8 Hz, 1H), 7.20-7.09 (m, 2H).

### Synthesis of Complex 44

44h (0.6 g, 1.37 mmol, 1 e.q.), potassium tetrachloroplatinate (0.68 g, 1.65 mmol, 1.2 e.q.) and tetrabytylammonium bromide (50 mg) were dissolved in acetic acid (150 mL) in a 250 mL single-neck flask. Under nitrogen protection, the mixture was stirred and reacted at 135° C. for 24 hours. After the mixture was cooled to room temperature, water was added in the reaction mixture to separate a solid out, and the resultant was filtrated to obtain a crude product. The crude product was recrystallization with dichloromethane/n-hexane (1/1) to obtain 0.68 g of orange red powder, and the productive rate was 61.1%.

¹H NMR (500 MHz, Chloroform-d) δ 9.04-8.99 (m, 1H), 8.92-8.85 (m, 2H), 8.07 (dd, J=7.8, 1.4 Hz, 1H), 7.98 (d, J=7.9 Hz, 1H), 7.94-7.82 (m, 4H), 7.70 (dd, J=6.2, 1.5 Hz, 1H), 7.65 (d, J=1.8 Hz, 1H), 7.61 (td, J=7.7, 1.3 Hz, 1H), 7.50 (t, J=2.1 Hz, 1H), 7.46 (d, J=2.1 Hz, 2H), 7.37-7.26 (m, 2H), 7.26-7.19 (m, 2H), 7.15 (s, 1H), 1.35 (s, 18H).

¹³C NMR (125 MHz, Common NMR Solvents) δ 151.61, 151.39, 146.36, 145.17, 144.49, 141.94, 141.55, 140.21, 138.95, 138.62, 137.58, 135.86, 134.94, 132.33, 129.58, 129.48, 127.69, 127.65, 127.25, 127.23, 127.07, 123.93, 123.91, 123.71, 122.60, 121.96, 121.93, 121.79, 121.33, 119.84, 116.12, 111.84, 110.52, 96.22, 34.96, 31.29.

ESI-HRMS (m/z): 818.883 (M+1).

### Fifth Embodiment: Synthesis of Complex 98

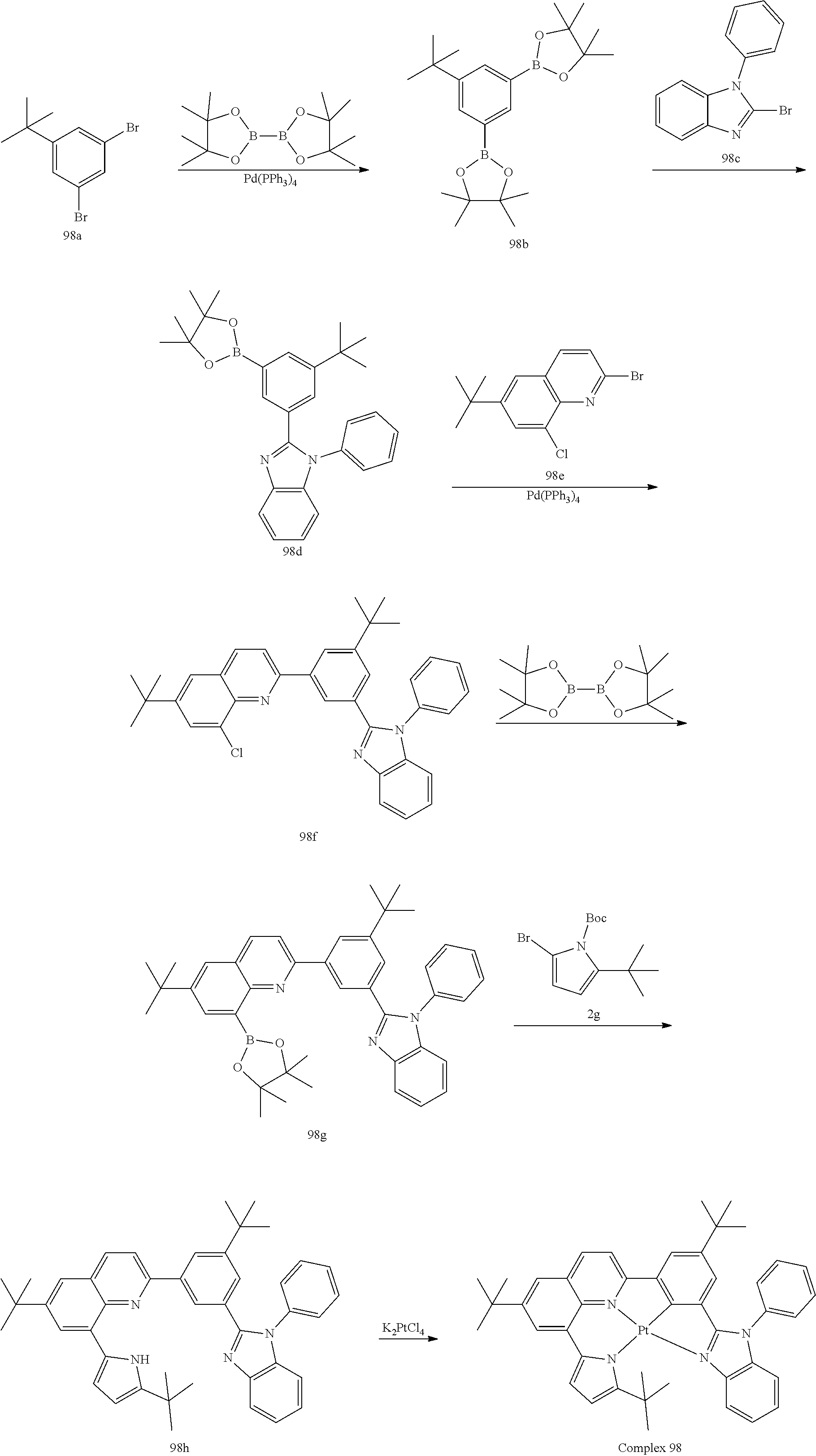

### Synthesis of Complex 98b

98a (10.0 g, 34.2 mmol, 1.e.q), bis(pinacolato)diboron (26.09 g, 102.7 mmol, 3 e.q.), potassium acetate (10.1 g, 102.7 mmol, 3 e.q.), Pd(dppf)₂Cl₂ (0.5 g, 0.68 mmol, 0.02 e.q.) and methylbenzene (500 mL) were added in a flask. The mixture was stirred at room temperature for 30 minutes, heated to 80° C., and stirred and reacted for 10 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, and dried with anhydrous sodium sulfate. The mixture was subjected to a reduced pressure distillation process to evaporate and remove the solvent. The resultant was separated with silica gel chromatographic column chromatography method, 8.1 g of white powder was obtained, and the productive rate was 61.1%.

¹H NMR (500 MHz, Chloroform-d) δ 7.75 (t, J=2.2 Hz, 1H), 7.56 (d, J=2.2 Hz, 2H), 1.35 (s, 9H), 1.24 (s, 24H).

### Synthesis of Complex 98d

98c (3.77 g, 13.8 mmol, 1 e.q.), 98b (8 g, 20.7 mmol, 1.5 e.q.), tetrakis(triphenylphosphine) palladium (0.32 g, 0.28 mmol, 0.02 e.q.), potassium carbonate solution (2 M, 20.7 mL, 3 e.q.) and methylbenzene (200 mL) were added in a three-neck flask under nitrogen protection. The reaction system was subjected to a vacuum process and nitrogen was injected into the reaction system, and the processes repeated for three times. Then the mixture was heated to 60° C. and reacted, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 3.9 g of white solid was obtained, and the productive rate was 63.2%.

¹H NMR (500 MHz, Chloroform-d) δ 7.98 (t, J=2.2 Hz, 1H), 7.90-7.83 (m, 1H), 7.74-7.67 (m, 1H), 7.59 (t, J=2.1 Hz, 1H), 7.54 (t, J=2.1 Hz, 1H), 7.51-7.44 (m, 2H), 7.44-7.37 (m, 3H), 7.33-7.28 (m, 2H), 1.35 (s, 9H), 1.24 (s, 12H).

### Synthesis of Complex 98f

98e (2.3 g, 7.6 mmol, 1 e.q.), 98d (3.8 g, 8.4 mmol, 1.1 e.q.), tetrakis(triphenylphosphine) palladium (0.17 g, 0.15 mmol, 0.02 e.q.), potassium carbonate solution (2 M, 11.4 mL, 3 e.q.) and methylbenzene (60 mL) were added in a three-neck flask under nitrogen protection. The reaction system was subjected to a vacuum process and nitrogen was injected into the reaction system, and the processes repeated for three times. Then the reaction mixture was heated to 80° C. and reacted, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 2.98 g of white solid was obtained, and the productive rate was 72.3%.

¹H NMR (500 MHz, Chloroform-d) δ 8.41 (t, J=2.2 Hz, 1H), 8.08 (dd, J=8.1, 2.3 Hz, 1H), 7.90-7.83 (m, 3H), 7.80 (dt, J=9.9, 2.2 Hz, 2H), 7.73-7.66 (m, 1H), 7.60 (d, J=2.2 Hz, 1H), 7.51-7.44 (m, 2H), 7.44-7.37 (m, 3H), 7.33-7.27 (m, 2H), 1.36 (s, 18H).

### Synthesis of Complex 98 g

98f (2.8 g, 5.15 mmol, 1.e.q), bis(pinacolato)diboron (1.82 g, 7.7 mmol, 1.5 e.q.), potassium acetate (1.5 g, 15.5 mmol, 3 e.q.), Pd(dppf)₂Cl₂ (0.075 g, 0.103 mmol, 0.02 e.q.) and methylbenzene (100 mL) were added in a flask. The mixture was stirred at room temperature for 30 minutes, heated to 80° C., and stirred and reacted for 10 hours. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The organic phases were combined together, and dried with anhydrous sodium sulfate. The mixture was subjected to a reduced pressure distillation process to evaporate and remove the solvent. The resultant was separated with silica gel chromatographic column chromatography method, 2.68 g of white powder was obtained, and the productive rate was 82%.

¹H NMR (500 MHz, Chloroform-d) δ 8.42 (t, J=2.2 Hz, 1H), 8.14 (dd, J=8.1, 2.2 Hz, 1H), 7.93 (d, J=8.0 Hz, 1H), 7.90-7.80 (m, 4H), 7.73-7.66 (m, 1H), 7.58 (d, J=2.0 Hz, 1H), 7.51-7.41 (m, 2H), 7.44-7.37 (m, 2H), 7.33-7.27 (m, 2H), 1.35 (d, J=7.1 Hz, 18H), 1.24 (s, 12H).

### Synthesis of Complex 98h

98 g (2.5 g, 3.94 mmol, 1 e.q.), 2 g (1.3 g, 4.33 mmol, 1.1 e.q.), tetrakis(triphenylphosphine) palladium (0.09 g, 0.08 mmol, 0.02 e.q.), potassium carbonate solution (2 M, 5.91 mL, 3 e.q.) and methylbenzene (50 mL) were added in a three-neck flask. The reaction system was subjected to a vacuum process and nitrogen was injected into the reaction system, and the processes repeated for three times. Then the reaction mixture was heated to 80° C. and reacted, and stirred overnight. After the reaction mixture was cooled to room temperature, the mixture was extracted with ethyl acetate. An organic phase was washed with a saturated sodium chloride solution for three times, dried with anhydrous sodium sulfate, and then subjected to a reduced pressure distillation process to evaporate and remove the solvent. The resultant was separated with silica gel chromatographic column chromatography method, 1.21 g of yellow solid was obtained, and the productive rate was 48.9%.

¹H NMR (500 MHz, Chloroform-d) δ 8.69 (s, 1H), 8.42 (t, J=2.2 Hz, 1H), 8.13 (dd, J=8.1, 2.4 Hz, 1H), 7.89 (d, J=8.0 Hz, 1H), 7.89-7.82 (m, 3H), 7.80 (t, J=2.2 Hz, 1H), 7.72-7.66 (m, 1H), 7.63 (d, J=2.0 Hz, 1H), 7.51-7.44 (m, 2H), 7.47-7.37 (m, 4H), 7.33-7.27 (m, 2H), 6.31 (d, J=6.8 Hz, 1H), 1.35 (s, 27H).

### Synthesis of Complex 98

72b (1.10 g, 1.75 mmol, 1 e.q.) and potassium tetrachloroplatinate (0.52 g, 2.1 mmol, 1.2 e.q.) and tetrabytylammonium bromide (50 mg) were dissolved in acetic acid (100 mL) in a 250 mL single-neck flask. Under nitrogen protection, the mixture was stirred and reacted at 135° C. for 24 hours. After the mixture was cooled to room temperature, water was added in the reaction mixture to separate a solid out, and the resultant was filtrated to obtain a crude product. The crude product was recrystallization with dichloromethane/n-hexane (1/1) to obtain 1.16 g of orange red powder, and the productive rate was 81.3%.

¹H NMR (500 MHz, Chloroform-d) δ 8.19 (dd, J=6.8, 1.4 Hz, 1H), 8.12-8.06 (m, 2H), 7.98 (dd, J=8.2, 2.2 Hz, 1H), 7.92-7.86 (m, 2H), 7.57 (d, J=8.2 Hz, 1H), 7.49-7.46 (m, 2H), 7.44-7.39 (m, 1H), 7.39-7.34 (m, 2H), 7.30 (d, J=2.2 Hz, 1H), 7.26 (td, J=7.0, 0.8 Hz, 1H), 7.06 (td, J=7.1, 1.3 Hz, 1H), 6.46 (d, J=6.0 Hz, 1H), 6.17 (d, J=6.0 Hz, 1H), 1.36 (s, 27H).

¹³C NMR (125 MHz, Common NMR Solvents) δ 155.88, 152.05, 151.70, 149.75, 147.24, 142.52, 139.89, 138.85, 138.13, 136.84, 136.54, 136.29, 130.61, 129.79, 129.05, 128.49, 128.37, 128.35, 127.75, 125.43, 124.26, 124.02, 123.78, 123.57, 123.18, 122.76, 118.88, 114.51, 107.80, 107.41, 38.62, 35.11, 34.93, 31.37, 31.27, 29.88.

ESI-HRMS (m/z): 822.318 (M+1).

It should be appreciated by those skilled in the art that the above methods of preparation are only exemplary embodiments. Those skilled in the art are able to obtain other compound structures of the present invention by improving them.

### Sixth Embodiment

An organic light emitting diode was made by the luminescent material made of the complex in the present disclosure, and a structure of the device was shown in the FIGURE.

Firstly, a transparent conductive ITO glass substrate 10 (with an anode 20) was successively washed with a detergent solution, deionized water, ethanol, acetone and deionized water, and then subjected to oxygen plasma treatment for 30 seconds.

Then, an HATCN layer having a thickness of 10 nm was coated on the ITO glass substrate as an electron hole injection layer 30 by method of vapor deposition.

Then, compound HT was coated on the HATCN layer by method of vapor deposition to form an electron hole transport layer 40 having a thickness of 40 nm.

Then, a luminescent layer 50 having a thickness of 20 nm was coated on the electron hole transport layer by method of vapor deposition. The luminescent layer was consisted of the platinum complex 2 (20%) and CBP (80%).

Then, AlQ₃ was coated on the luminescent layer by method of vapor deposition to form an electron transport layer 60 having a thickness of 40 nm.

Finally, a LiF electron injection layer 70 having a thickness of 1 nm and a Al device cathode 80 having a thickness of 100 nm were coated by method of vapor deposition.

### Seventh Embodiment

The complex 2 was replaced with the complex 10, and an organic light emitting diode was made by the method described in the sixth embodiment.

### Eight Embodiment

The complex 2 was replaced with the complex 20, and an organic light emitting diode was made by the method described in the sixth embodiment.

### Ninth Embodiment

The complex 2 was replaced with the complex 44, and an organic light emitting diode was made by the method described in the sixth embodiment.

### Tenth Embodiment

The complex 2 was replaced with the complex 98, and an organic light emitting diode was made by the method described in the sixth embodiment.

### First Comparative Embodiment

The complex 2 was replaced with the complex Ref-1 (U.S. Ser. No. 10/566,566B2), and an organic light emitting diode was made by the method described in the sixth embodiment.

In the devices, HATCN, HT, AlQ₃, Ref-1 and RH had the structures as shown hereinafter.

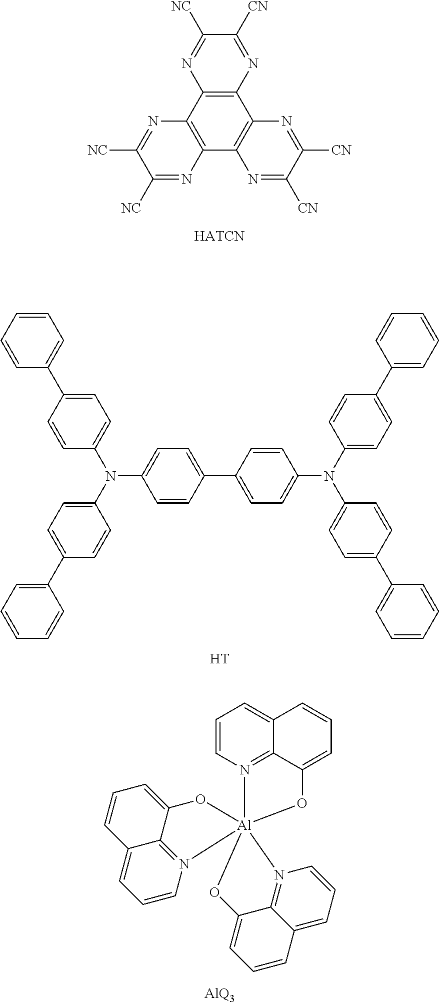

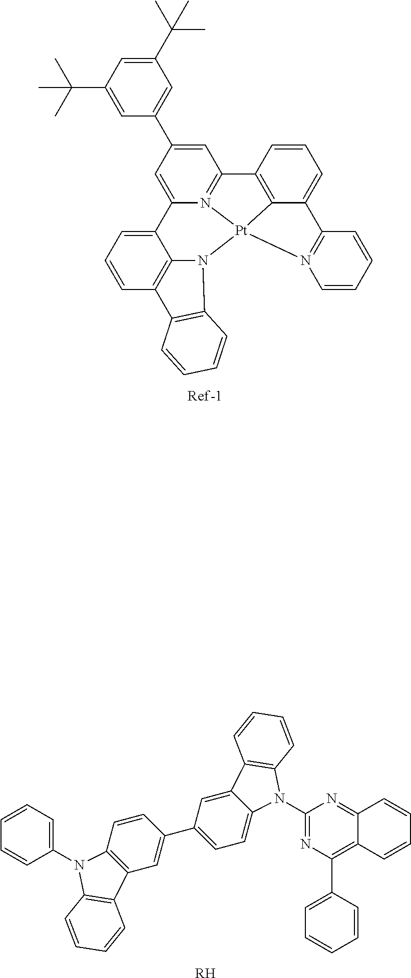

Device performances of the organic electroluminescent devices in the sixth embodiment to tenth embodiment under current density of 10 mA/cm² were listed in table 1 herein.

TABLE 1

| | | | Lumines- | Light | Device |
|---|---|---|---|---|---|
| | | Driving | cence | Emitting | Lifetime |
| Device No. | Complex | Voltage | Efficiency | Color | (Lt98) |
| Sixth | Second | 0.98 | 1.02 | Dark Red | 0.80 |
| Embodiment | Complex | | | | |
| Seventh | Complex | 0.98 | 1.03 | Dark Red | 0.89 |
| Embodiment | 10 | | | | |
| Eighth | Complex | 0.96 | 1.07 | Dark Red | 0.90 |
| Embodiment | 20 | | | | |
| Ninth | Complex | 0.96 | 1.11 | Dark Red | 1.13 |
| Embodiment | 44 | | | | |
| Tenth | Complex | 0.94 | 1.17 | Dark Red | 1.07 |
| Embodiment | 98 | | | | |
| First | Ref-1 | 1 | 1 | Orange | 1 |
| Comparative | | | | | |
| Embodiment | | | | | |

Comment: The device performance test took the first comparative example as the benchmark, and each index of the first comparative example was set as 1; and Lt98 indicated the time when the brightness of the device decreases to 98% of the initial brightness (10000 Cd/M²).

It can be concluded from table 1 that, under the same conditions, the platinum complex materials in the present disclosure can be used to prepare organic light emitting diodes emitting a dark red light, and had a lower driving voltage and a higher luminescence efficiency. In addition, the organic light emitting diodes made of the complex of the present disclosure had significantly better service life than organic light emitting diodes made of the complex in the comparative embodiments, and can meet requirements of the industry to the luminescent material and had good industrial prospect.

The foregoing plurality of embodiments are intended as examples only and are not intended to limit the scope of the present disclosure. Without departing from the spirit of the present disclosure, a wide variety of materials and structures in the present disclosure may be replaced with other materials and structures. It should be understood that many modifications and variations can be made by a person skilled in the art without creative labor along the lines of the present disclosure. Therefore, the technical solutions that can be obtained by the skilled person through analysis, reasoning or partial research on the basis of the prior art shall be within the scope of protection limited by the claims.

What is claimed is:

1. A platinum complex having NNCN tetradentate ligand as shown in formula (I), 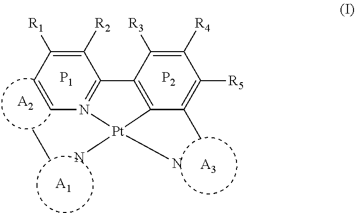
wherein A₁ and A₃ are each independently selected from R₀ substituted or unsubstituted N-containing C₄-C₆₀ heteroaryl groups,
A₂ is selected from R₀ substituted or unsubstituted C₆-C₆₀ aryl groups, or substituted or unsubstituted C₄-C₆₀ heteroaryl groups;
a ring formed by coordination bonds of A₁, A₂, P₁ and Pt is a six-membered ring;
a ring formed by coordination bonds of P₁, P₂ and Pt is a five-membered ring;
a ring formed by coordination bonds of P₂, A₃ and Pt is a five-membered ring;
R₀-R₅ are each independently selected from hydrogen atom, deuterium atom, halogen, amino group, carbonyl group, carboxyl group, alkythio, cyano group, sulfonyl group, phosphino group, substituted or unsubstituted C₁-C₂₀ alkyl groups, substituted or unsubstituted C₃-C₂₀ cycloalkyl groups, substituted or unsubstituted C₂-C₂₀ alkenyl groups, substituted or unsubstituted C₁-C₂₀ alkoxyl groups, substituted or unsubstituted C₆-C₃₀ aryl groups, or substituted or unsubstituted C₃-C₃₀ heteroaryl groups, or adjacent R₀-R₅ groups are capable of forming rings;
wherein substituted groups are selected from halogen, amino group, cyano group or C₁-C₄ alkyl groups; and
heteroatoms in the heteroaryl group is selected from the group consisting of N, S, O, and any combination thereof.

2. The platinum complex of claim 1, wherein R₀-R₅ are each independently selected from hydrogen atom, deuterium atom, halogen, amino group, alkythio, cyano group, substituted or unsubstituted C₁-C₆ alkyl groups, substituted or unsubstituted C₃-C₆ cycloalkyl groups, substituted or unsubstituted C₂-C₆ alkenyl groups, substituted or unsubstituted C₁-C₆ alkoxyl groups, substituted or unsubstituted C₆-C₁₂ aryl groups, or substituted or unsubstituted C₃-C₆ heteroaryl groups.

3. The platinum complex of claim 2, wherein R₀-R₅ are each independently selected from hydrogen atom, deuterium atom, halogen, C₁-C₄ alkyl groups, cyano group, substituted or unsubstituted C₃-C₆ cycloalkyl groups, substituted or unsubstituted C₆-C₁₂ aryl groups, or substituted or unsubstituted C₃-C₆ heteroaryl groups.

4. The platinum complex of claim 3, wherein R₀-R₅ are each independently selected from hydrogen atom, deuterium atom, methyl group, iso-propyl group, iso-butyl group, tert-butyl group, cyano group, substituted or unsubstituted cyclopentyl group, substituted or unsubstituted cyclohexyl group, substituted or unsubstituted phenyl group, substituted or unsubstituted pyridyl group, substituted or unsubstituted pyrazinyl group, or substituted or unsubstituted pyrimidyl group.

5. The platinum complex of claim 1, wherein A₁ is selected from R₀ substituted or unsubstituted C₄-C₂₀ heteroaryl groups, which comprises at least one N atom; and a ring formed by coordination bonds of A₁, A₂ and Pt is a five-membered N substituted heterocyclic ring or a six-membered N substituted heterocyclic ring.

6. The platinum complex of claim 5, wherein A₃ is selected from R₀ substituted or unsubstituted C₄-C₂₀ heteroaryl groups, which comprises one N atom or two N atoms; and a ring formed by coordination bonds of A₃ and Pt is a five-membered N substituted heterocyclic ring or a six-membered N substituted heterocyclic ring.

7. The platinum complex of claim 6, wherein A₂ is selected from R₀ substituted or unsubstituted C₆-C₂₀ aryl groups, or substituted or unsubstituted C₄-C₂₀ heteroaryl groups.

8. The platinum complex of claim 7, wherein A₂ is selected from R₀ substituted or unsubstituted C₄-C₁₂ heteroaryl groups, which comprises at least one N atom; and a ring formed by coordination bonds of A₂ and A₁ is a five-membered N substituted heterocyclic ring or a six-membered N substituted heterocyclic ring, and a position of A₂ bonded to A₁ is the N atom.

9. The platinum complex of claim 1, wherein A₁ is selected from following groups, and dotted lines represent a bond between A₁ and A₂,

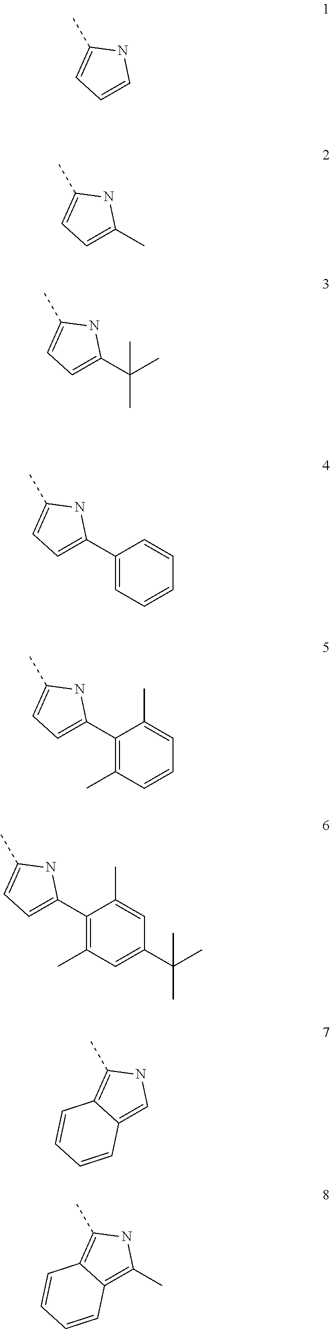

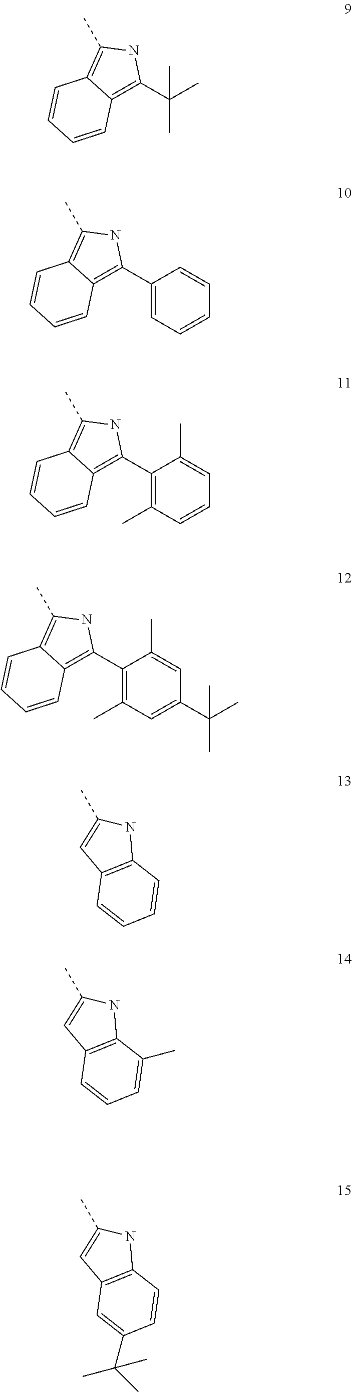

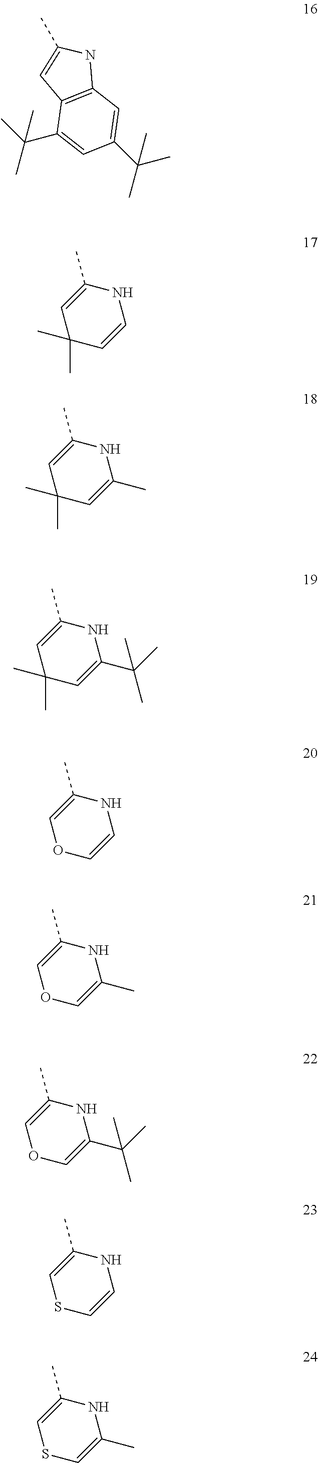

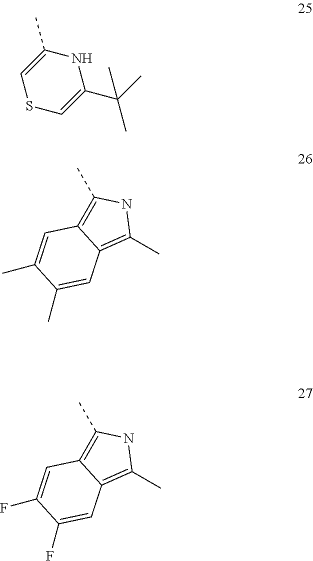

10. The platinum complex of claim 1, wherein A₂ is selected from following groups, and dotted lines represent a bond between A₁ and A₂,

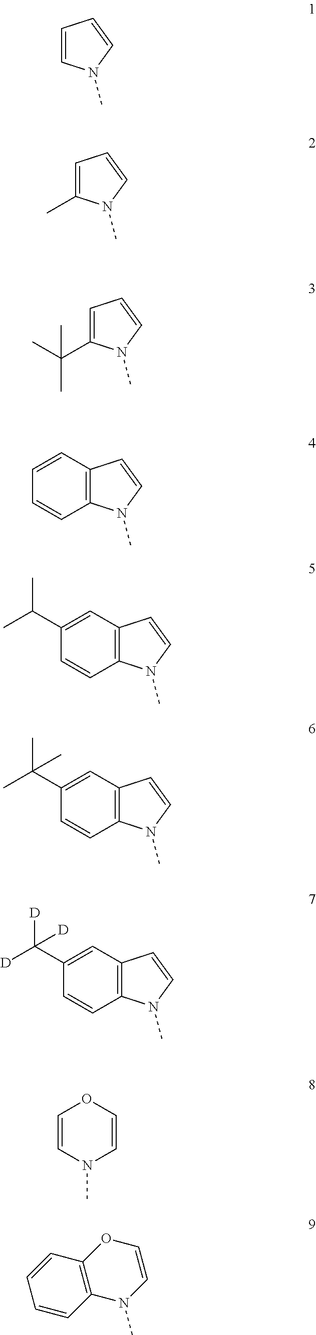

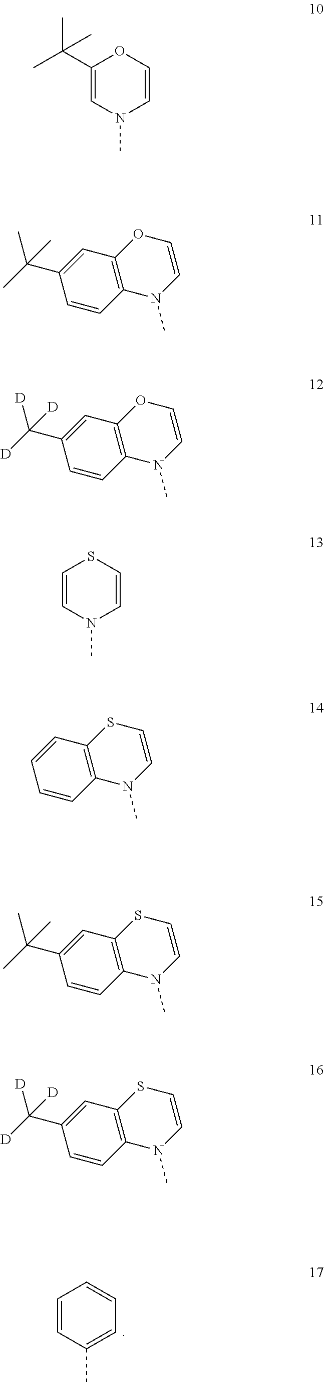

11. The platinum complex of claim 1, wherein A₃ is selected from following groups, and dotted lines represent a bond between A₃ and P₂,

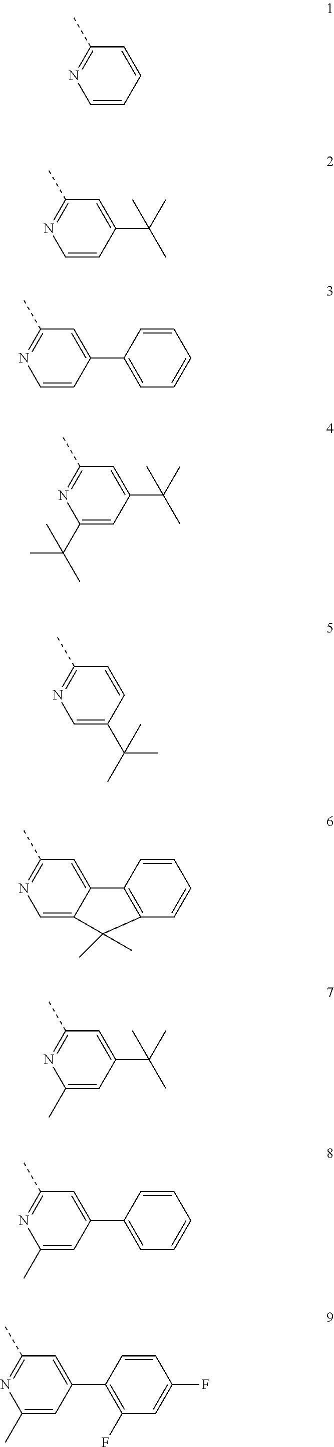

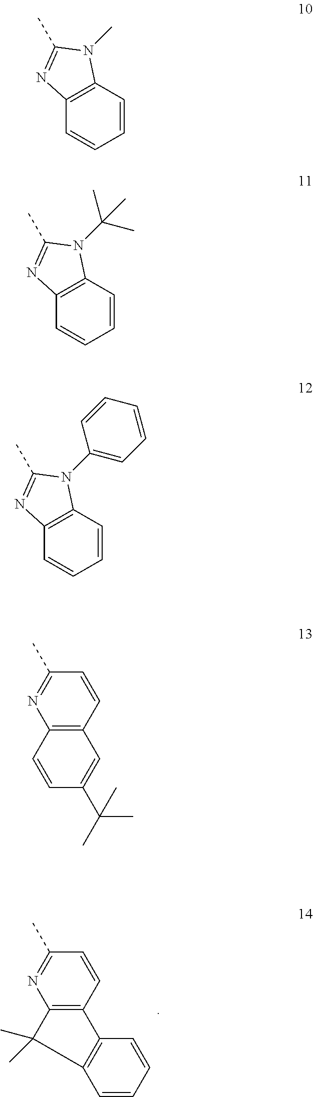

12. The platinum complex of claim 1, wherein the formula (I) is selected from one of following structures,

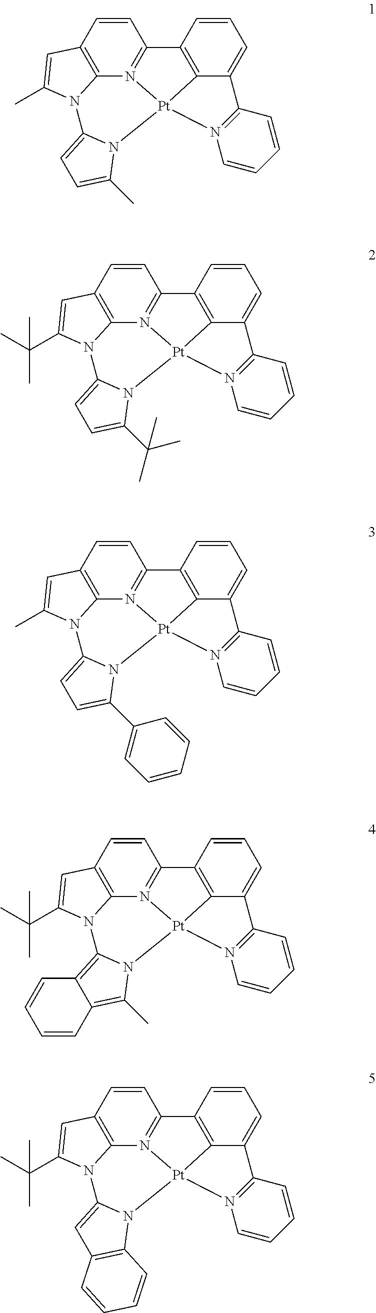

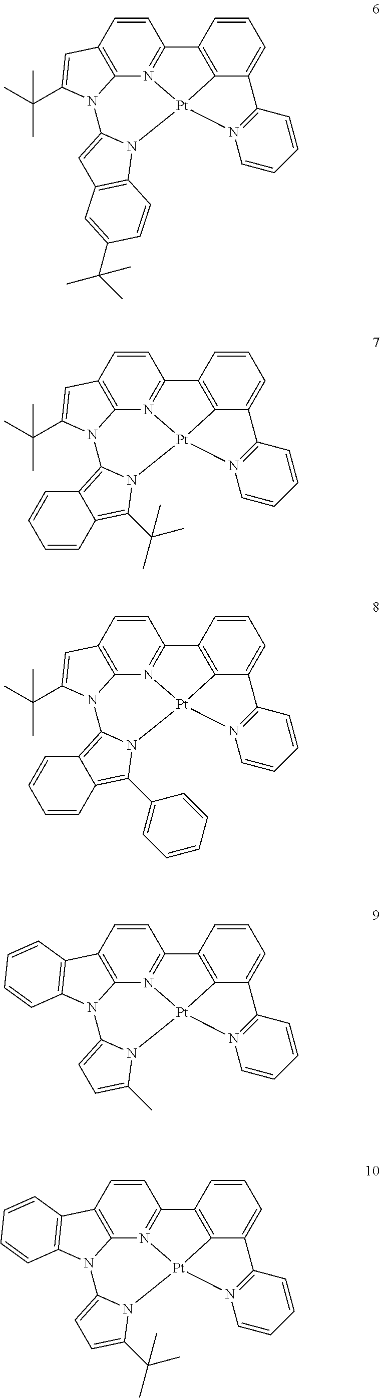

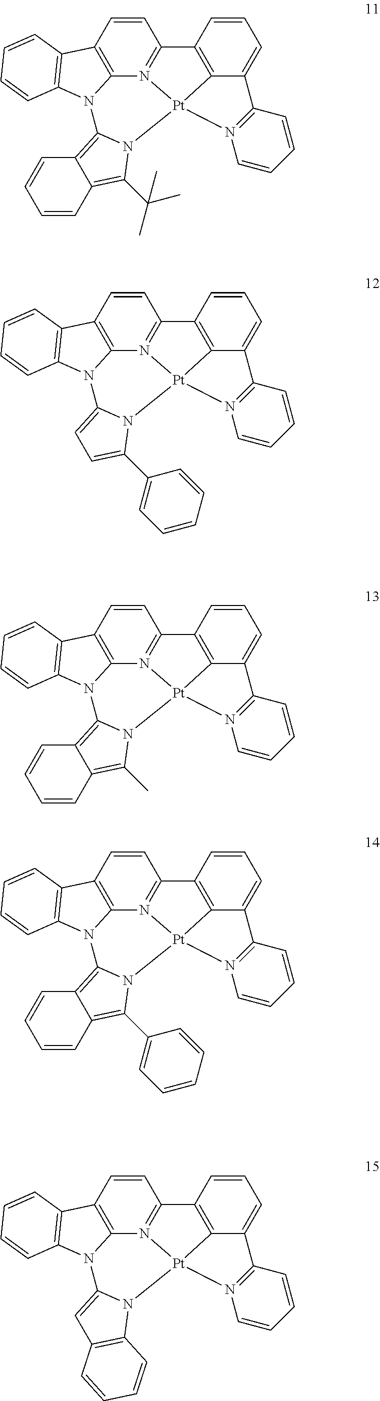

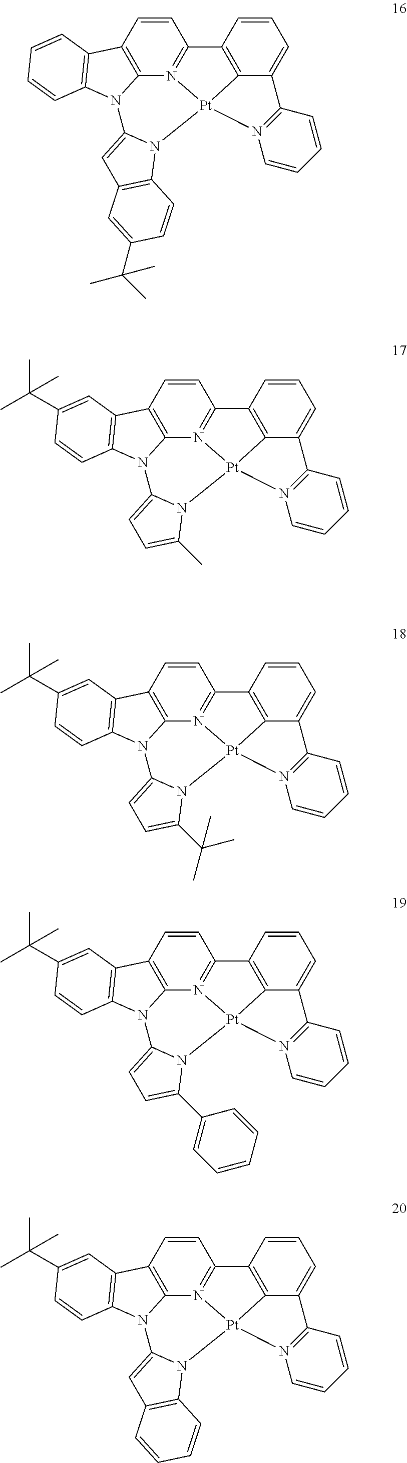

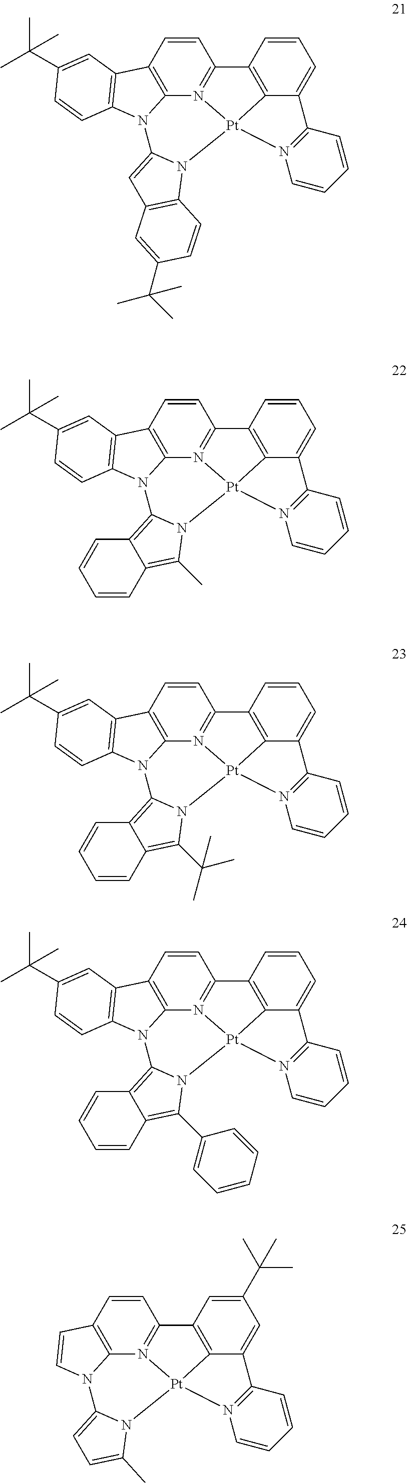

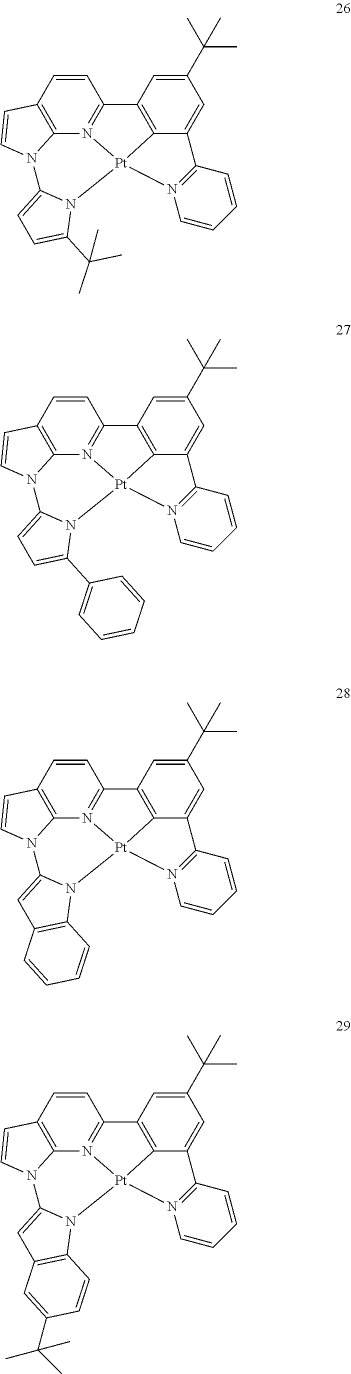

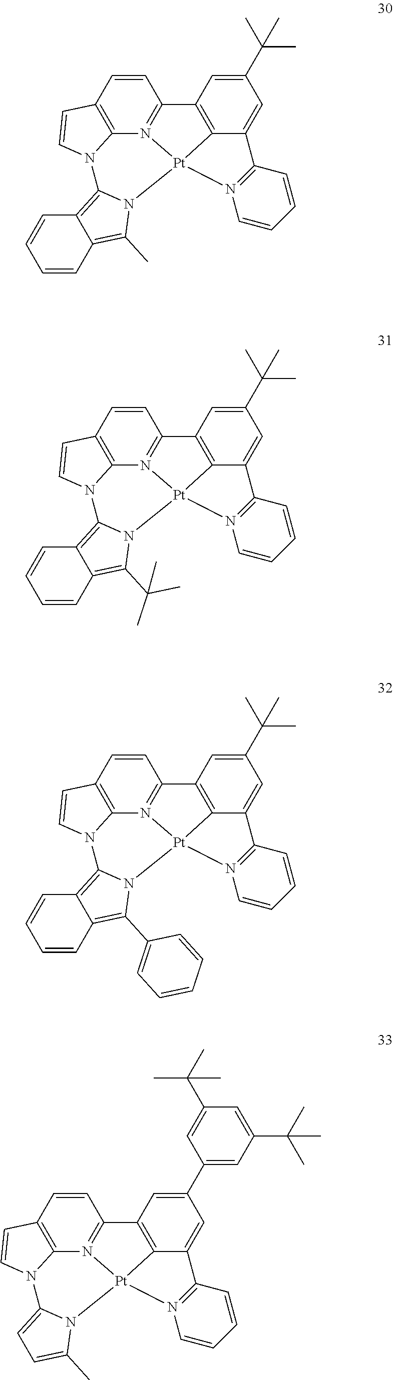

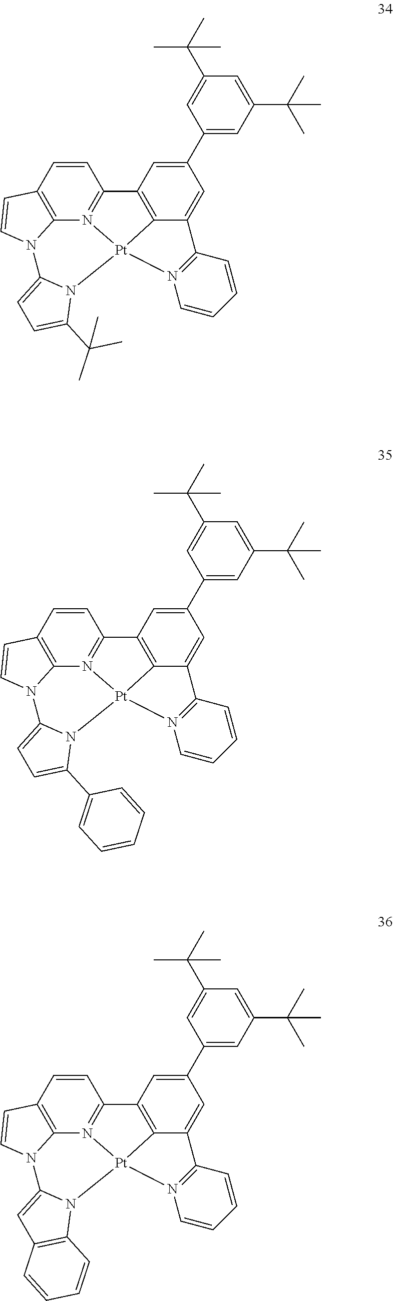

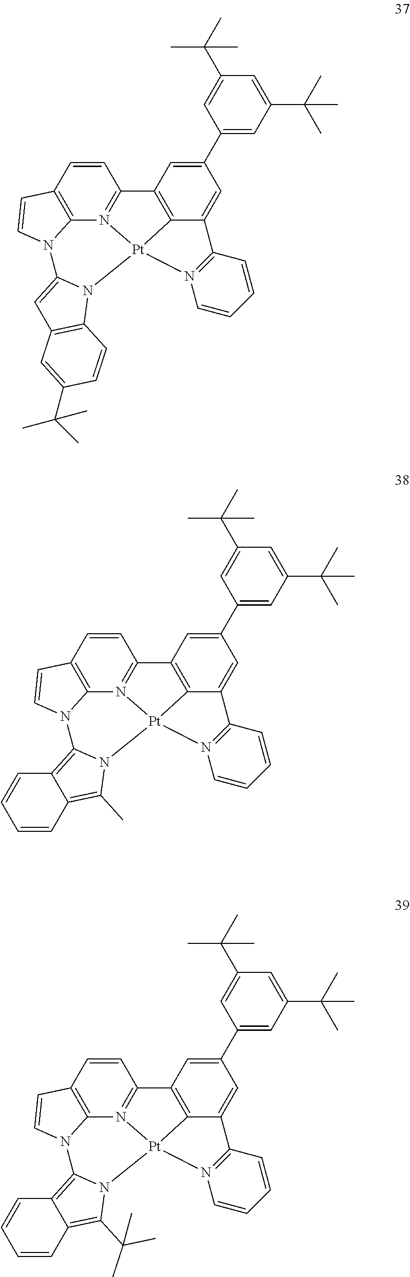

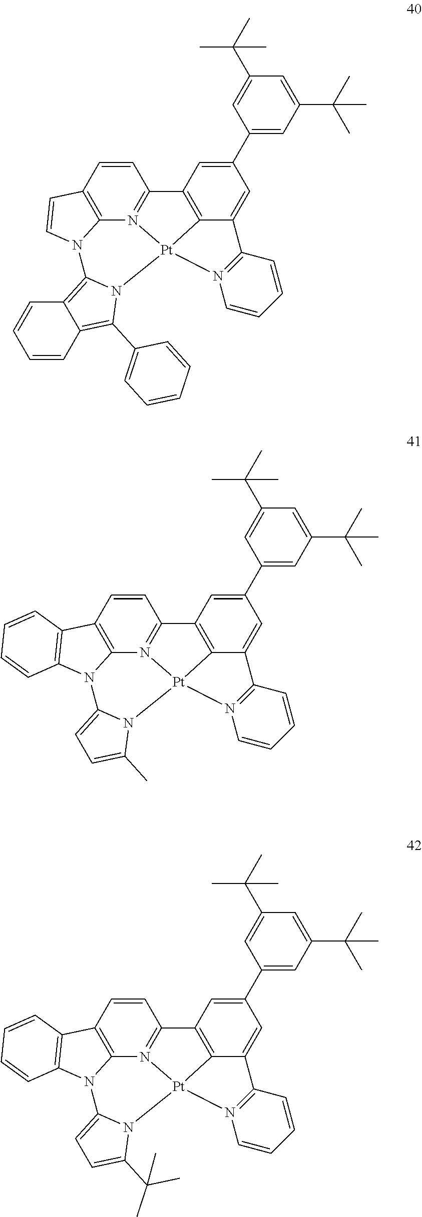

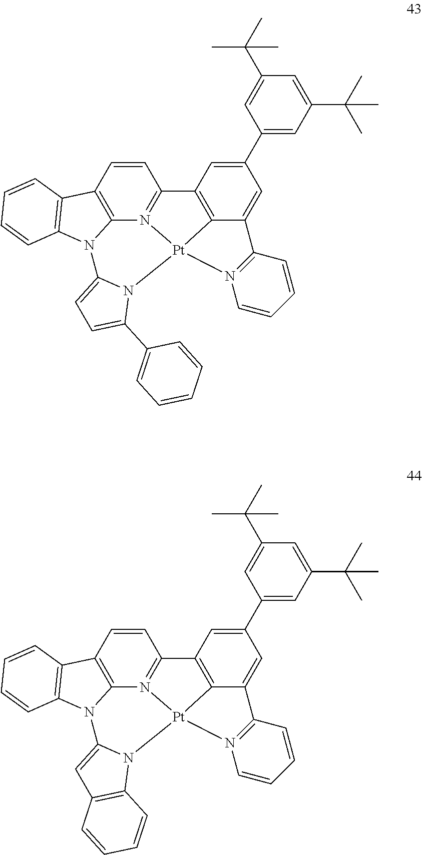

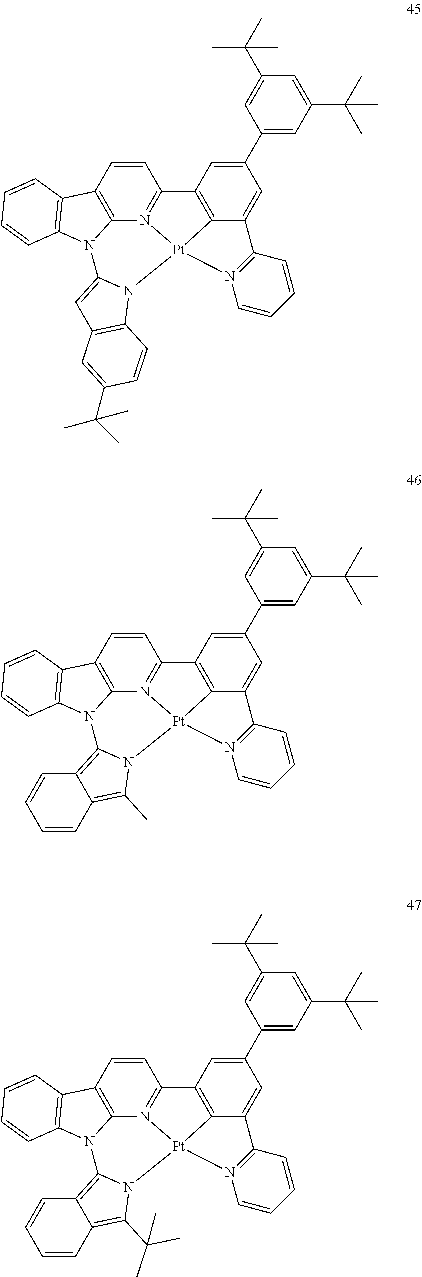

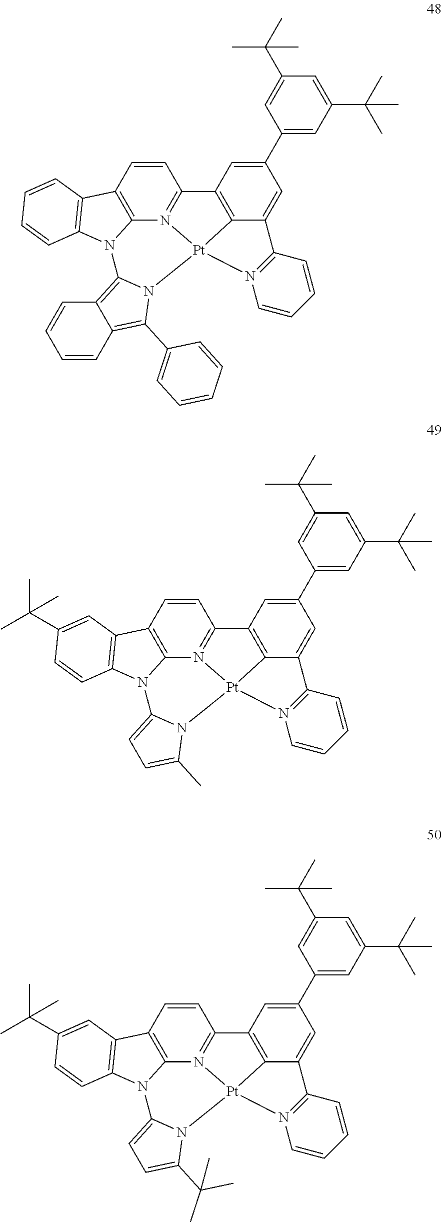

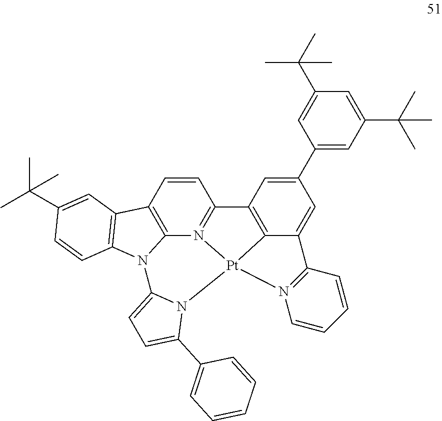

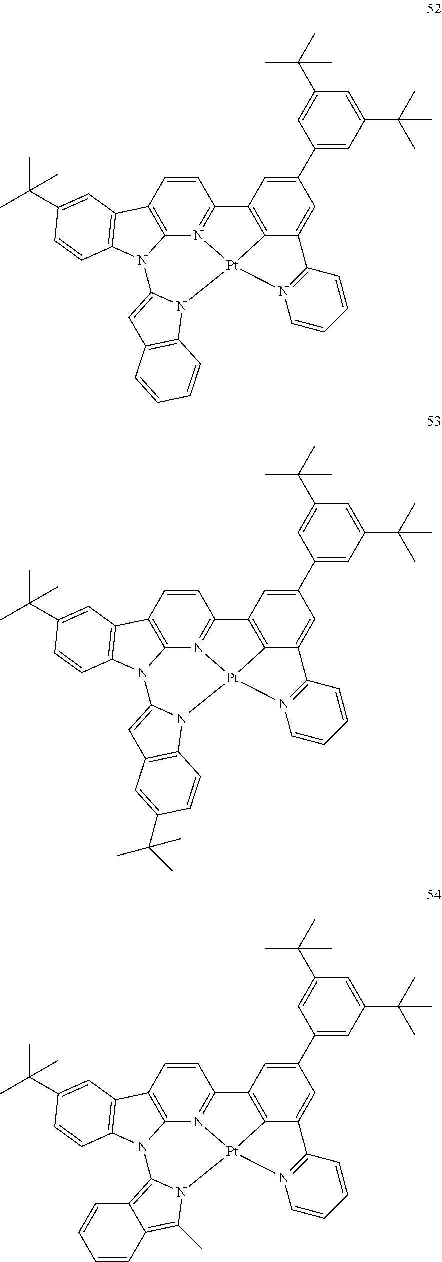

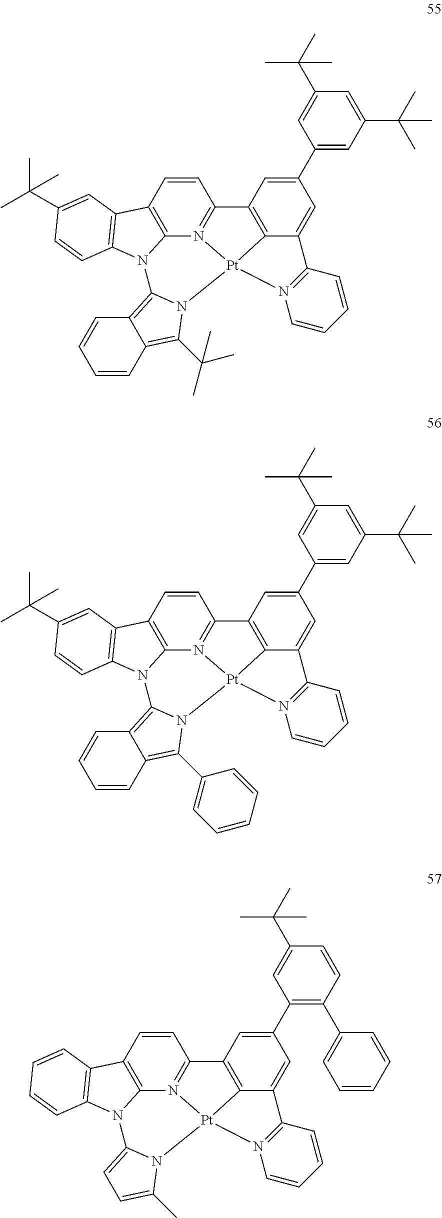

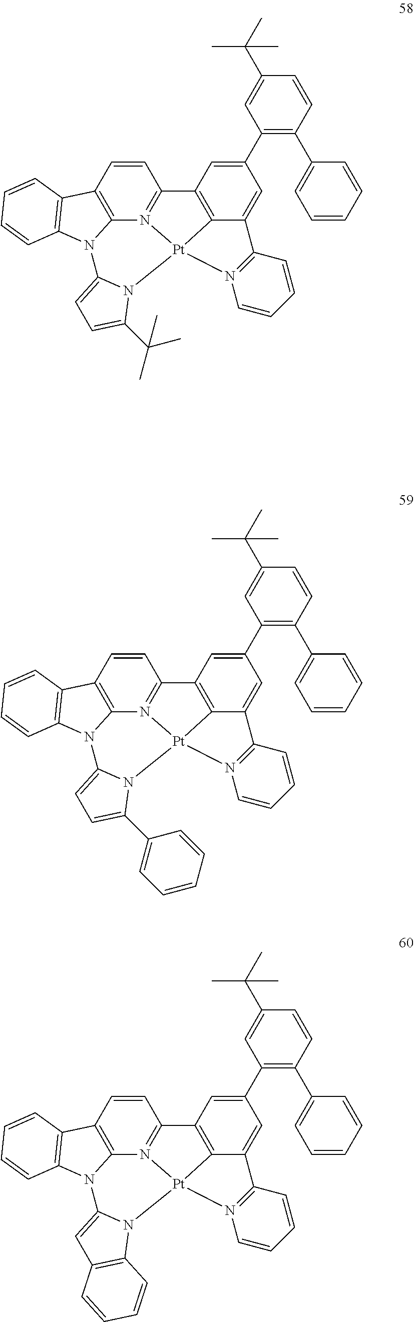

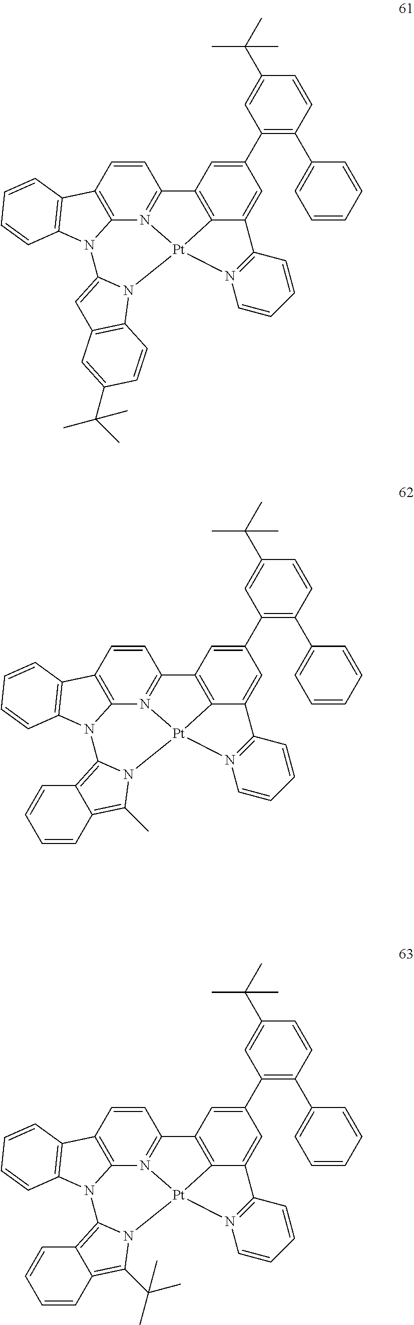

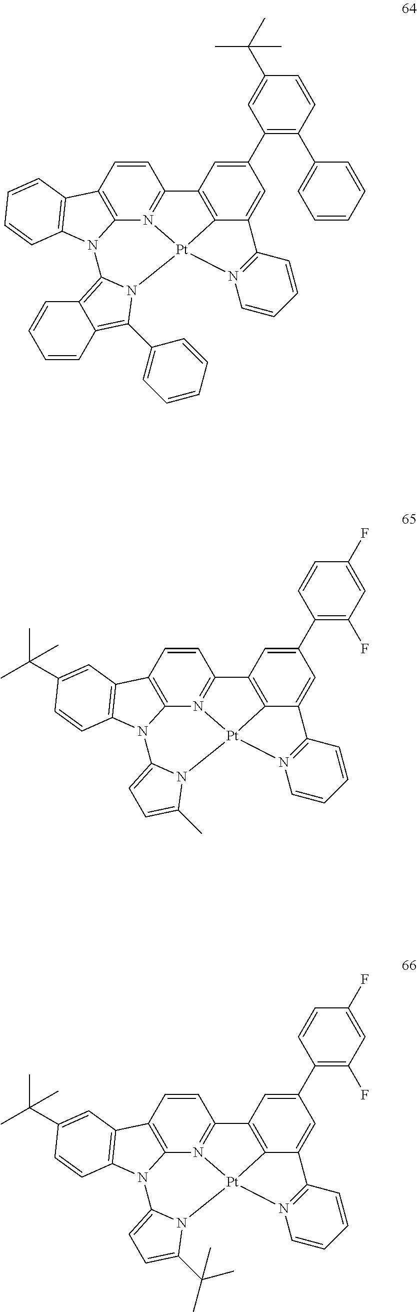

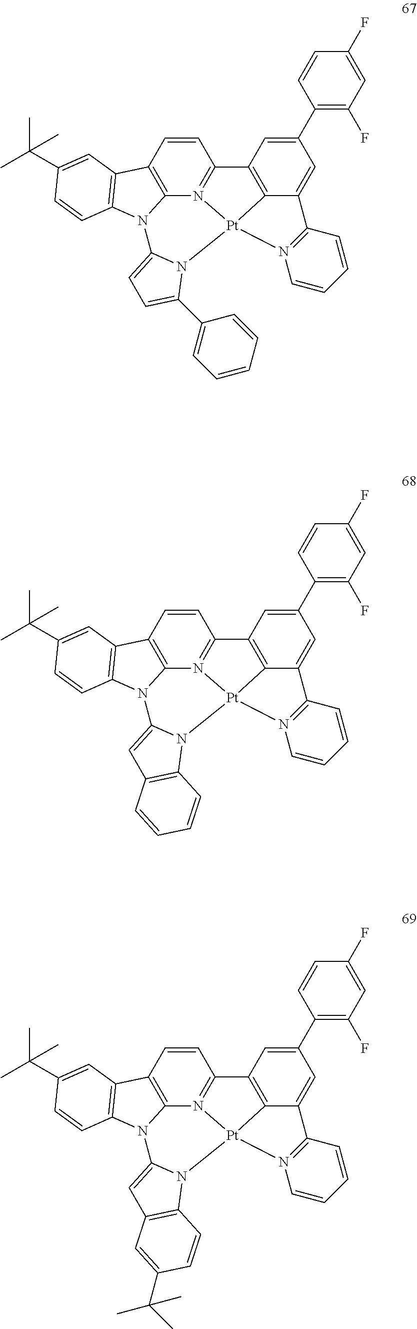

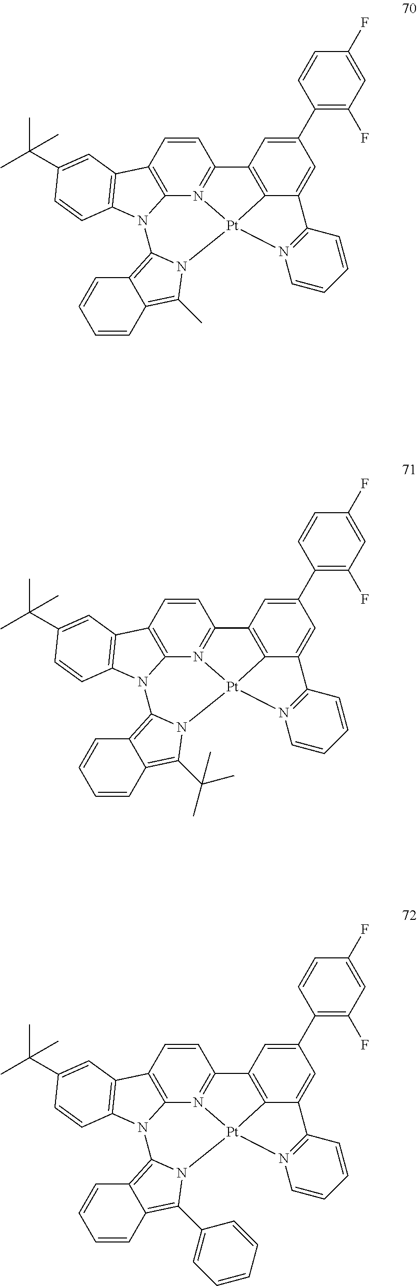

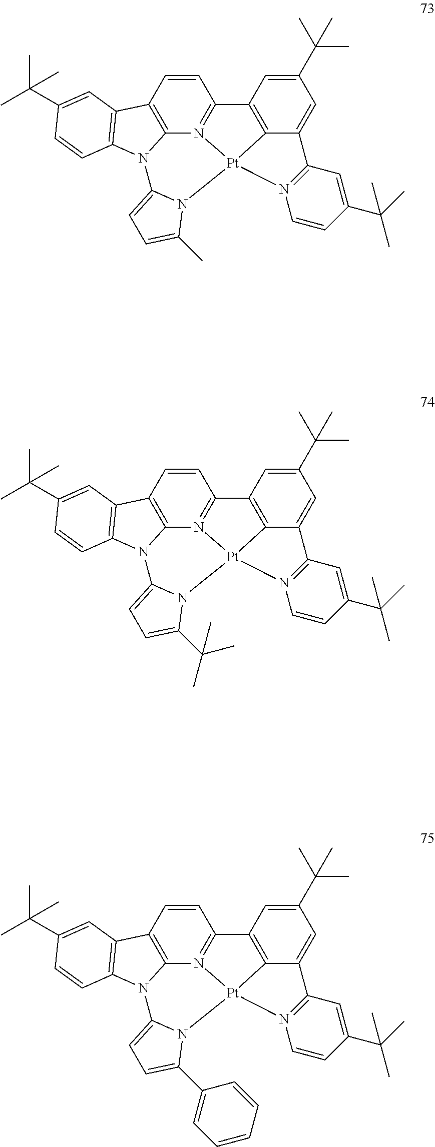

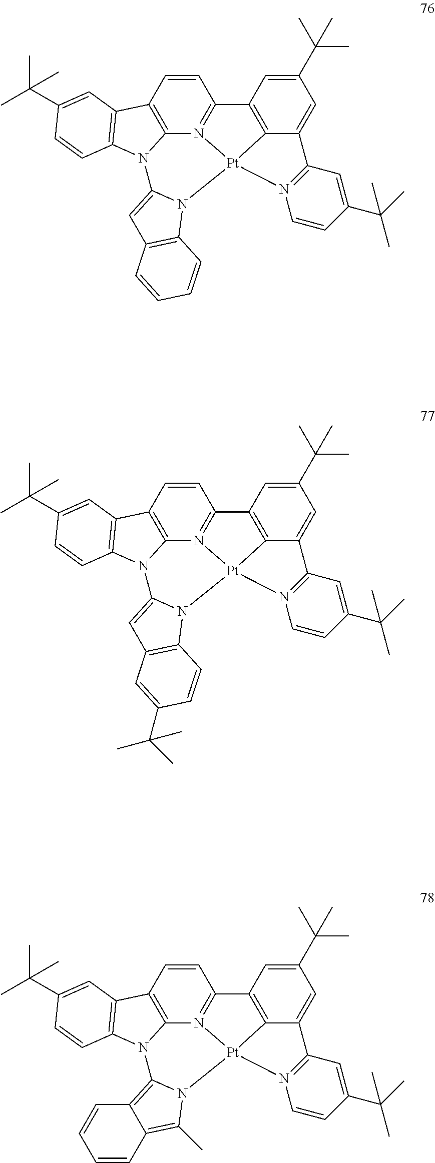

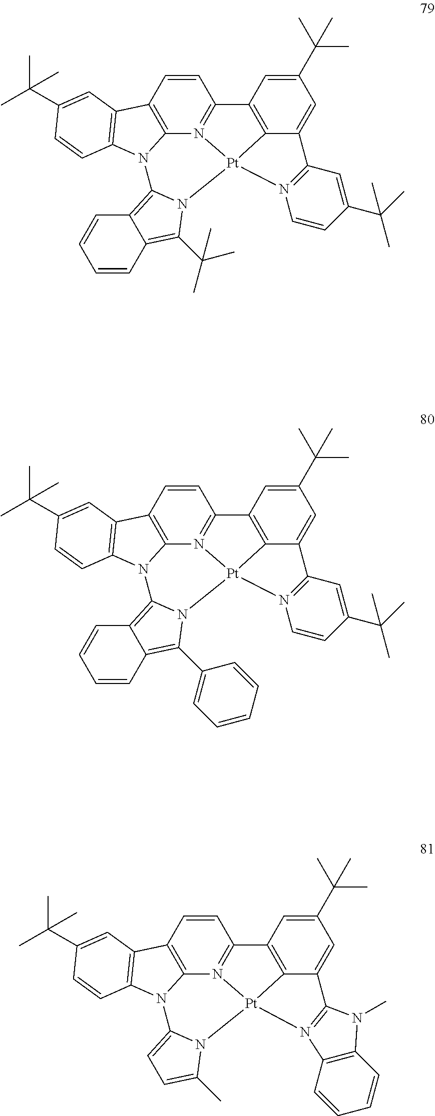

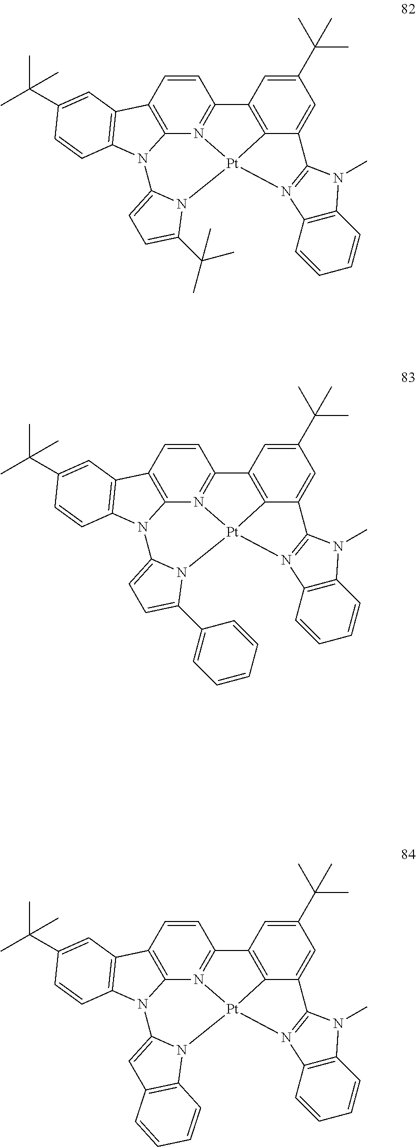

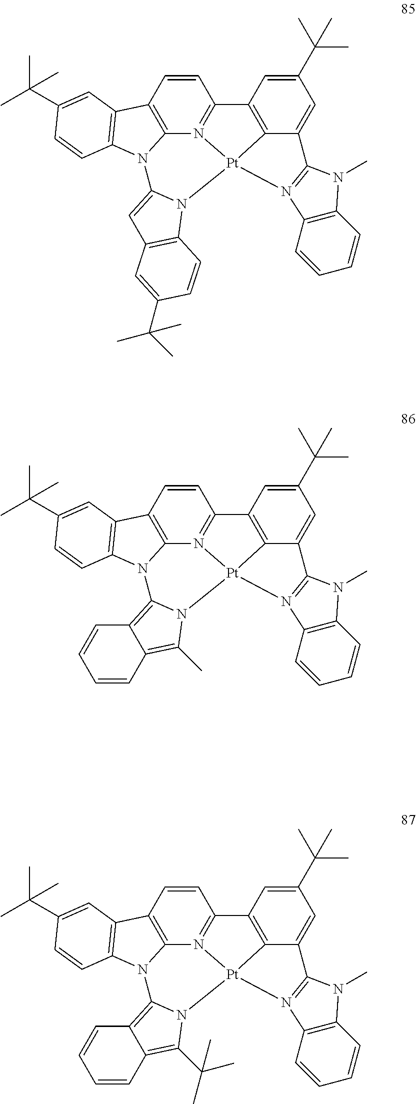

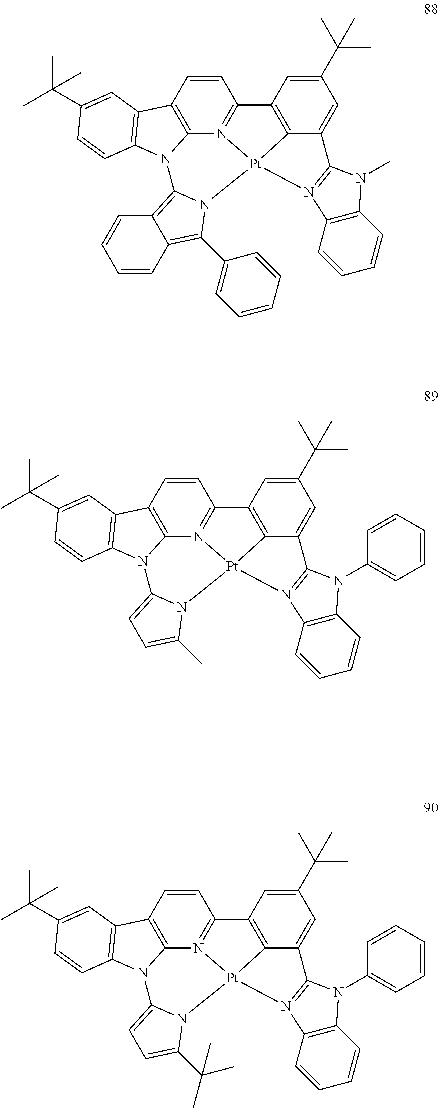

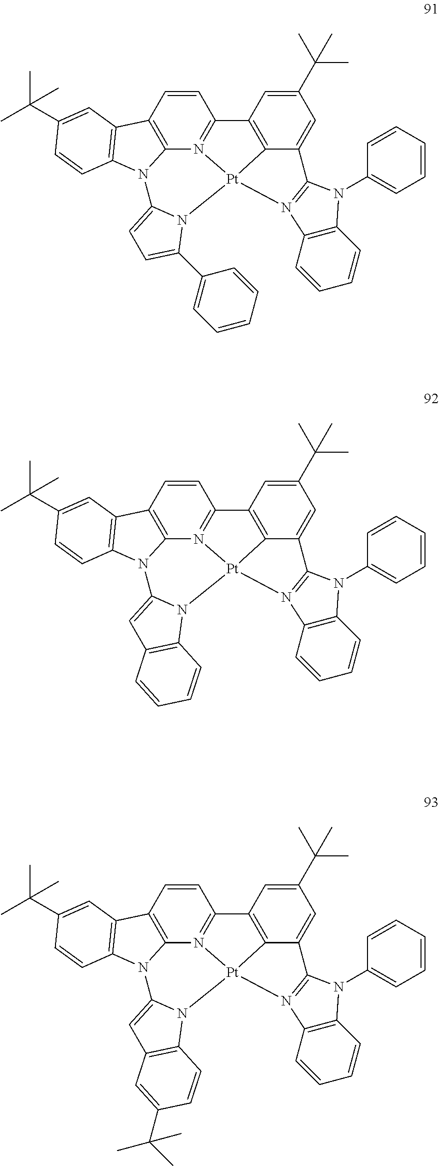

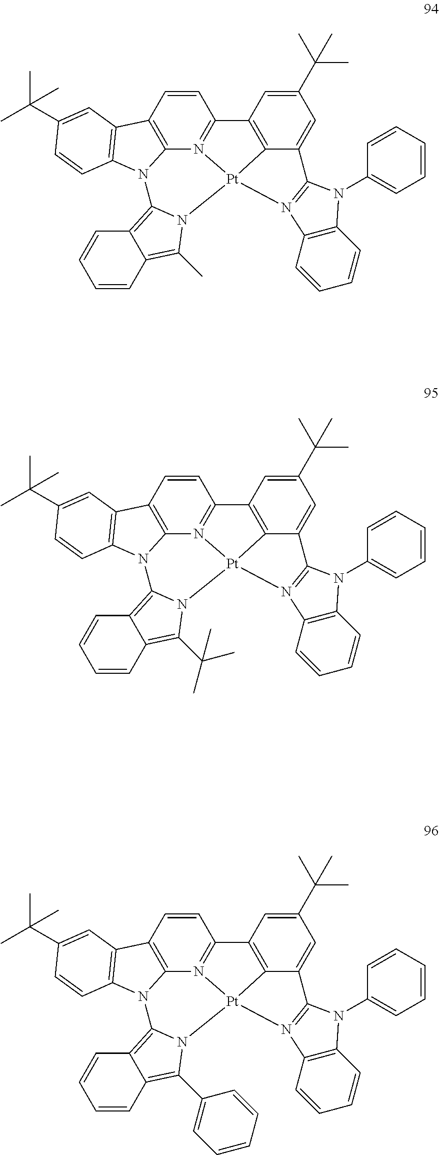

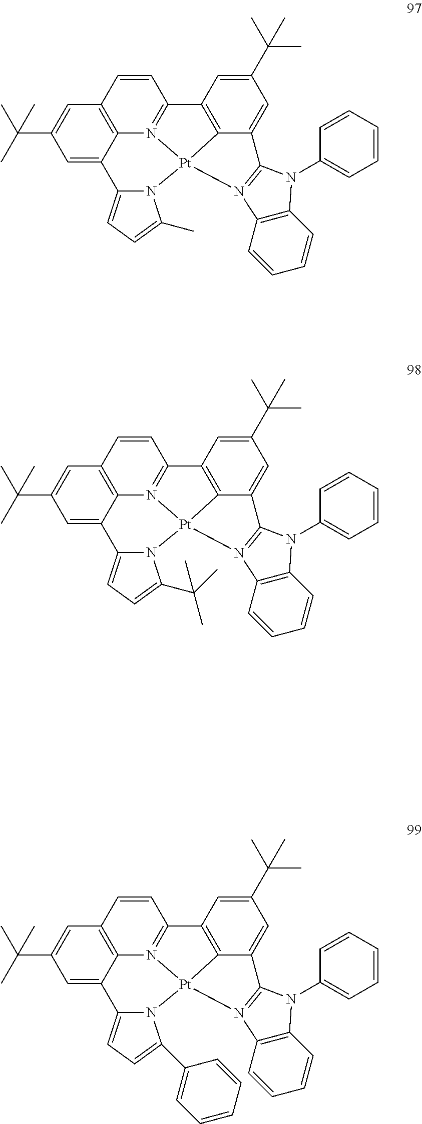

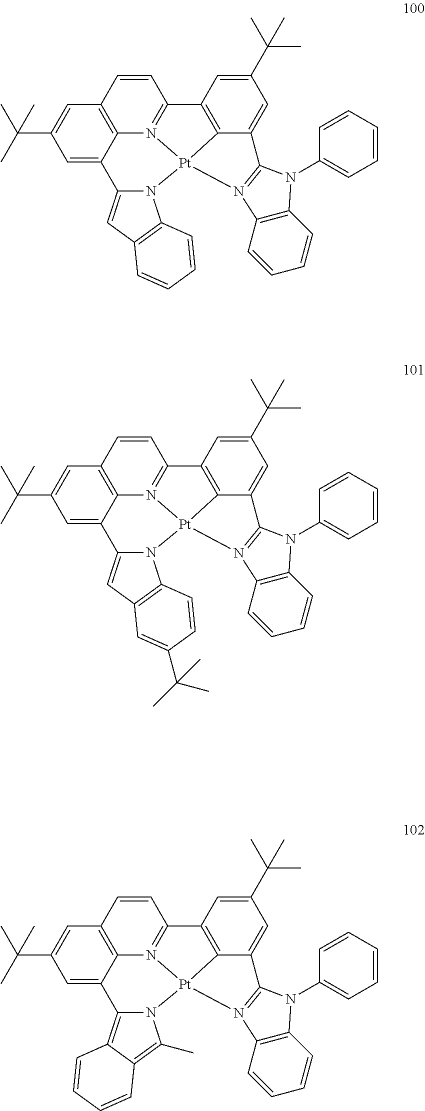

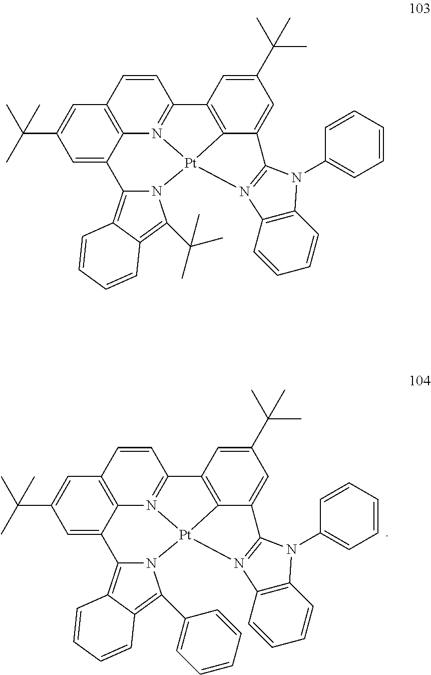

13. A precursor of the platinum complex of claim 1, wherein the precursor is a ligand, as shown in a formula as below:

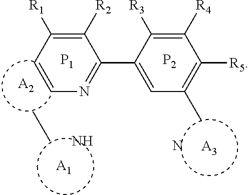

14. An organic photoelectronic device, comprising the platinum complex of claim 1, wherein the organic photoelectronic device is selected from organic light emitting diodes, organic thin-film transistors, organic photovoltaic devices, light emitting electrochemical cells or chemical sensors.

15. An organic light emitting diodes, comprising a cathode, an anode and an organic layer, wherein the organic layer is selected from the group consisting of an electron hole injection layer, an electron hole transport layer, a luminescent layer, an electron hole blocking layer, an electron injection layer, an electron transport layer, and any combination thereof; and, at least one of the electron hole injection layer, the electron hole transport layer, the electron hole blocking layer, the electron injection layer, the luminescent layer and the electron transport layer comprises the platinum complex of claim 1.

16. The organic light emitting diode of claim 15, wherein the platinum complex is used as a luminescent material of the luminescent layer, or an electron transport material of the electron transport layer.
